(19) United States
(12) Patent Application Publication
(10) Pub. No.: US 2024/0260482 A1
(43) Pub. Date: Aug. 1, 2024

(54) SUPERCONDUCTING JOSEPHSON DISORDERED NEURAL NETWORKS

(71) Applicant: THE REGENTS OF THE UNIVERSITY OF CALIFORNIA, Oakland, CA (US)

(72) Inventors: Robert Dynes, La Jolla, CA (US); Uday Goteti, San Diego, CA (US)

(21) Appl. No.: 18/293,167

(22) PCT Filed: Jul. 28, 2022
(86) PCT No.: PCT/US2022/038717

§ 371 Date: Jan. 29, 2024

Related U.S. Application Data
(60) Provisional application No. 63/226,743, filed on Jul. 28, 2021.

(51) Int. Cl. H10N 60/12; G06N 3/063; G06N 10/40; H10N 60/80; H10N 69/00

(52) U.S. Cl. CPC H10N 60/12; G06N 3/063; G06N 10/40; H10N 60/805; H10N 69/00

(57) ABSTRACT

Methods, systems, and devices for neural networks and neuromorphic computing are disclosed. In one implementation, a neural network includes an array of superconducting loops to store information, the superconducting loops multiply coupled to each other inductively or through Josephson junctions linking the superconducting loops, one or more input channels coupled to the array of superconducting loops to carry spiking input voltage signals to the array of superconducting loops, and one or more output channels coupled to the array of superconducting loops to carry spiking output voltage signals from the array of superconducting loops.

### CROSS-REFERENCE TO RELATED APPLICATION

This patent document claims priority to and benefits of U.S. Provisional Appl. No. 63/226,743, entitled “SUPERCONDUCTING JOSEPHSON DISORDERED NEURAL NETWORKS” and filed on Jul. 28, 2021. The entire contents of the before-mentioned patent application are incorporated by reference as part of the disclosure of this document.

### STATEMENT REGARDING FEDERALLY SPONSORED RESEARCH OR DEVELOPMENT

This invention was made with government support under DE-SC0019273 awarded by Quantum Materials for Energy Efficient Neuromorphic Computing (Q-MEEN-C) funded by the U.S. Department of Energy, Office of Science, Basic Energy Sciences. The government has certain rights in the invention.

### TECHNICAL FIELD

The disclosed embodiments relate to neural networks and neuromorphic computing.

### BACKGROUND

Neuromorphic computing has been gaining more and more interest recently due to several reasons. For example, it provides a power-efficient alternative to digital computing, it can be used to solve the von Neumann bottleneck between the processor and memory, and it can simulate aspects of and provide better understanding of a biological brain. Depending upon the problem, different hardware approaches and models of the network elements in the neuron are being considered.

### SUMMARY

The technology disclosed in this patent document can be used to provide an array of disordered superconducting loops for neural networks and neuromorphic computing.

In an implementation of the disclosed technology, a neural network include a plurality of disordered superconducting loops, at least one of the superconducting loops is coupled to one or more of the other superconducting loops through at least one of Josephson junction or inductor formed between the at least one of the superconducting loops and the one or more of the other superconducting loops; a plurality of input channels coupled to the neural network to apply input signals to the plurality of disordered superconducting loops; a plurality of output channels coupled to the neural network to receive output signals generated by the plurality of disordered superconducting loops in response to the input signals and transmit the output signals to another neural network; and a plurality of bias signal channels coupled to the neural network to apply bias signals to the plurality of disordered superconducting loops.

In another implementation of the disclosed technology, a neural network includes an array of superconducting loops to store information, the superconducting loops multiply coupled to each other inductively or through Josephson junctions linking the superconducting loops; one or more input channels coupled to the array of superconducting loops to carry spiking input voltage signals to the array of superconducting loops; and one or more output channels coupled to the array of superconducting loops to carry spiking output voltage signals from the array of superconducting loops, wherein the information is encoded in an amplitude and a timing of the spiking input and output voltage signals.

In another implementation of the disclosed technology, a method of storing information in an array of superconducting loops includes performing an excitation operation on the array of superconducting loops by applying input voltage signals and bias signals to the array of superconducting loops to store information in the superconducting loops in categories of different memory states based on combinations of the spiking input voltage signals and the bias signals, and performing a relaxation operation after performing the excitation operation to form energy barriers that separate the different memory states from each other.

The above and other aspects and implementations of the disclosed technology are described in more detail in the drawings, the description and the claims.

### BRIEF DESCRIPTION OF THE DRAWINGS

FIG. 1A shows an example of superconducting Josephson disordered neural network based on some implementations of the disclosed technology, FIG. 1B shows an example of simulation/numerical model, and FIG. 1C shows an experimental device.

FIG. 2A shows an example of fully recurrent neural network. FIG. 2B shows a disordered array synaptic network.

FIG. 3A shows a three-state synaptic network formed using two loops with one input, two outputs and two bias current channels. FIG. 3B shows an equivalent lumped-element circuit model with junctions and inductors.

FIGS. 4A-4D show relative current directions corresponding to four different configurations/synaptic weights possible in the symmetric 1×2 three-state synaptic network shown in FIGS. 3A-3B.

FIGS. 5A-5J shows the corresponding simulation results.

FIG. 6A shows 1×2 three-loop disordered array synaptic network with two feedback terminals. FIG. 6B shows equivalent lumped-element circuit model with junctions and inductors.

FIGS. 7A-7G show simulation results of the synaptic network shown in FIGS. 6A and 6B.

FIG. 8A shows two loops coupled to each other through an inductive element. FIG. 8B shows two loops coupled to each other through a Josephson junction.

FIGS. 9A-9H show simulation results of the two loop circuits shown in FIGS. 8A and 8B.

FIGS. 10A and 10B show leaky integrate-and-fire neuron circuit schematic.

FIG. 11A shows input spike train with constant magnitude and frequency. FIG. 11B shows output spike firing after the input signal reaches a threshold, for a given constant current bias. FIG. 11C shows loop current representing the total signal accumulated in the neuron. FIG. 11D shows varying frequency input signal obtained by applying a ramp current of a constant slope to the current bias. FIG. 11E shows output spike train corresponding to input as in FIG. 11D. FIG. 11F shows loop current accumulated in the neuron showing dependency on input frequency. FIG. 11G shows input current bias vs. output frequency.

FIG. 12A shows a feedback circuit to convert single-flux quantum pulses into current bias with a similar mechanism. FIG. 12B shows several feedback connections can be made to a single bias line.

FIGS. 13A-13D show simulation results of feedback circuits shown in FIGS. 12A and 12B.

FIG. 14A shows an example of regular network. FIG. 14B shows an example of small-world network. FIG. 14C shows an example of random disordered array synaptic network.

FIG. 15 shows neural network schematic illustrating feedback connections for a hierarchical architecture.

FIG. 16 shows a neural network schematic for the hierarchical architecture.

FIG. 17A shows 3-state synaptic network with 1 input, 2 outputs and 2 bias current channels. FIG. 17B shows a Josephson transmission line cell used at input, output and intermediate cells in all the circuits to verify that the designed cells can operate with any other circuits.

FIG. 18 shows voltage drop across each of the junctions of FIG. 17A with the bias conditions of FIG. 5B.

FIG. 19 shows 3-loop 1×2 disordered array synaptic network.

FIG. 20A shows voltage drop across each of the junctions of FIG. 19 with the bias conditions of FIG. 7B. FIG. 20B shows voltage drop across each of the junctions of FIG. 8B with the bias conditions of FIG. 9E.

FIGS. 21A-21C show schematic of 4×4 superconducting disordered loop neural networks with He-ion beam defined Josephson junctions.

FIGS. 22A-22E show experimental 3-loop 1×1 superconducting disordered neural network.

FIGS. 23A-23D show electrical characteristics-static operation.

FIGS. 24A and 24B show evolution of memory states observed as different rates of flow of flux.

FIG. 25 shows dynamic transitions between memory states dependent on relative phase difference of input signals.

FIG. 26 shows electrical scan of state-space of operation of 3-loop 1×1 superconducting neural network.

FIG. 27 shows control experiment-evolution of memory states observed as different rates of flow of flux.

FIG. 28 shows equivalent circuit model of the experimental 3-loop network.

FIGS. 29A-29D show comparison of experimental and simulation results.

FIG. 30 shows dynamic transitions between memory states dependent on relative phase difference of input signals from 0 to 2π.

FIG. 31 shows complete phase diagram of the dynamic memory states and the corresponding state transitions.

FIG. 32 shows electrical scan (inverted) of state-space of operation of 3-loop 1×1 superconducting neural network.

FIG. 33 shows disordered superconducting neural network showing trapped flux configurations and the corresponding circulating currents around loops.

FIG. 34A shows 3-loop neural network under uniform magnetic field pulse excitation followed by a relaxation period. FIG. 34B shows trapped flux energy representing memory states as a function of different magnetic field pulse amplitudes. FIG. 34C shows relaxed memory states with a constant bias current shows tilting of the energy profile.

FIG. 35A shows 3-loop neural network with a spiking input excitation signal followed by a relaxation period. FIG. 35B shows trapped flux energy during and after relaxation following a spiking excitation. FIG. 35C shows when bias is turned ON during spiking excitation, the resulting memory states are classified into categories retained during and after excitation. FIG. 35D shows when relaxed, large energy barriers separate these classes of states (S₁-S₅). FIG. 35E shows experimental observation of classes of states (S₁-S₅) in the form of different rates of flow of flux at the output.

FIG. 36 shows an example method of storing information in an array of superconducting loops based on some implementations of the disclosed technology.

### DETAILED DESCRIPTION

Disclosed are methods, devices and systems that pertain to a physical structure configured from a superconducting film which allows the writing and reading of information in a configuration which allows it to either self-learn or be instructed to learn. In some embodiments of the disclosed technology, an array of disordered superconducting loops can trap single magnetic fluxoids in a large variety of configurations and can provide a configurable/programmable platform to model generic features of neural networks. The disclosed technology can be implemented in some embodiments to provide various applications in the area of practical neural networks/neuromorphic computing.

The recognition of the advantage of disorder of the loop configurations and the disorder in the superconducting critical currents allows for an exponential increase in the information with increasing loop numbers. Each loop can be smaller than a micron in diameter and so a device on the scale of a millimeter can have exponentially increasing density of information. Only 25 loops can have 10**12 states. Furthermore, each movement of information (each device switch) consumes attojoules. The networks, in some embodiments of the disclosed technology, use spiking voltage inputs and generate spiking voltage outputs analogous to biological brains. The functionality of the neural networks can be controlled using physical parameters of the array on hardware, as well as being programmed using additional time-dependent current inputs.

The disclosed technology can be used in some embodiments to implement a physical structure configured from a superconducting film which allows the writing and reading of information in a configuration which allows it to either self-learn or be instructed to learn. In some implementations, the physical structure may include an array of disordered superconducting loops that can trap single magnetic fluxoids in a large variety of configurations and act as a logic element or memory. The physical structure implemented based on some embodiments of the disclosed technology can store different magnetic flux configurations which can serve as different memory configurations.

Neuromorphic devices/circuits fabricated from conventional materials and in conventional orientation results in higher energy dissipation, lower information density storage and limited configurability.

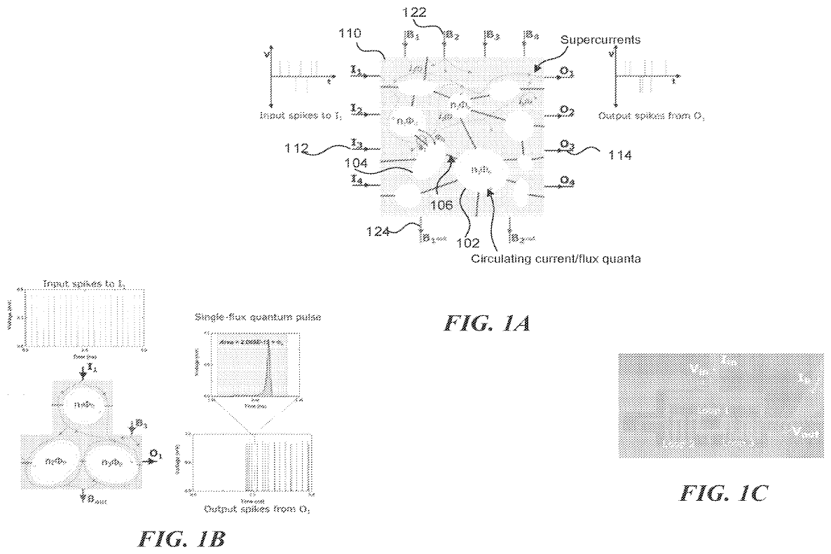

FIG. 1A shows an example of superconducting Josephson disordered neural network based on some implementations of the disclosed technology, FIG. 1B shows an example of simulation/numerical model, and FIG. 1C shows an example experimental device.

As shown in FIG. 1A, a neural network device implemented based on some embodiments of the disclosed technology can include a disordered array of superconducting loops 102, 104 disposed in a superconducting material 110, wherein at least one 102 of the superconducting loops is coupled to at least one 104 of adjacent superconducting loops to form a Josephson junction 106. A plurality of input nodes 112 are coupled to a first end of the superconducting material 110 and are configured to receive spiking input voltages I₁-I₄. A plurality of output nodes 114 are coupled to a second end of the superconducting material 110 and are configured to provide spiking output voltages O₁-O₄. A plurality of bias current nodes 122, 124 are structured to apply bias currents B₁-B₄, B₁ₒᵤₜ, B₂ₒᵤₜ across the superconducting material 110.

As shown in FIG. 1B, a device that includes 3 superconducting loops can be fabricated to demonstrate the characteristics of the disordered array of superconducting loops containing Josephson junctions, and, as shown in FIG. 1C, an experimental device can include circuits corresponding to 3 superconducting loops, input nodes, output nodes and bias current nodes.

The disclosed technology can be implemented in some embodiments to provide superconducting neural networks with disordered Josephson junction array synaptic networks and leaky integrate-and-fire loop neurons.

In some embodiments of the disclosed technology, fully coupled randomly disordered recurrent superconducting networks with additional open-ended channels for inputs and outputs can introduce a new architecture to neuromorphic computing. Various building blocks of such a network are designed around disordered array synaptic networks using superconducting devices and circuits as an example, while emphasizing that a similar architectural approach may be compatible with several other materials and devices. A multiply coupled (interconnected) disordered array of superconducting loops containing Josephson junctions (equivalent to superconducting quantum interference devices (SQUIDs)) forms the aforementioned collective synaptic network that forms a fully recurrent network together with compatible neuron-like elements and feedback loops, enabling unsupervised learning. This approach aims to take advantage of superior power efficiency, propagation speed, and synchronizability of a small world or a random network over an ordered/regular network. Additionally, it offers a significant factor of increase in scalability. A compatible leaky integrate-and-fire neuron with superconducting loops with Josephson junctions is presented, along with circuit components for feedback loops as needed to complete the recurrent network. Several of these individual disordered array neural networks can further be coupled together in a similarly disordered way to form a hierarchical architecture of recurrent neural networks that is often suggested as similar to a biological brain.

As noted earlier, neuromorphic computing has been gaining more and more interest recently due to several reasons such as (1) an approach for a power-efficient alternative to digital computing, (2) a way to solve the problem of von Neumann bottleneck between the processor and memory, or (3) in simulating aspects and gaining a better understanding of a biological brain, etc. Depending upon the problem, different hardware approaches and models of the network elements in the neuron have been considered. For example, the Hodgkin-Huxley neuron model is a popular and accurate representation of a biological neuron and is used in spiking neural networks as well as mimicking biological behavior. The McCulloch-Pitts neuron model is popular with artificial neural networks that are used in convolutional neural networks. Similarly, biologically inspired synapse models are compatible with spiking neural networks and exhibit learning rules corresponding to spike timing-dependent plasticity. Also, artificial synapses for largely feed-forward and non-spiking networks are also available. The disclosed technology can be implemented in some embodiments to provide a novel approach to neuromorphic computing, which is not particularly designed to solve a specific problem in the existing computing paradigm, but to present a new architecture that may address several of the aforementioned aspects, while also attempting to provide an alternative perspective into the process of neuromorphic computing in general. Nevertheless, the superconducting network components considered here are compatible with spiking neural networks, and leaky integrate-and-fire neurons that may permit the development of a superconducting neural network can enable further exploration of the architecture.

There are two important aspects to consider when building a neural network. The first aspect involves identifying appropriate materials, devices, and circuits that closely emulate biological aspects of elements such as neurons, synapses, and dendrites. Several such materials and devices are being studied and implemented with some degree of success, particularly in studying memristive and phase-changing materials for synaptic connections and spiking behavior for neurons. The second aspect to consider involves scalability and power efficiency. A human brain comprises roughly 8:3×10⁹ neurons with about 6:7×10¹³ synaptic connections between them and consumes approximately 20 W of power. Replicating this using artificial circuit elements to achieve similar power efficiency and connectivity currently presents some severe challenges, although rapid progress is being made in this area.

The hardware challenges with respect to scalability can be addressed by increasing the density of processing power into smaller areas. A straightforward path to overcome this issue is by increasing the density of interconnections through further development of the IC fabrication techniques and also by decreasing the footprint of the individual elements used in the circuits. The disclosed technology can be implemented in some embodiments to provide a collective synaptic network approach that considerably improves the scalability of the already existing technologies by utilizing the exponential scaling of the memory capacity of disordered and coupled networks. For example, all the neurons in a network are connected to each other through a disordered array of superconducting loops encompassing Josephson junctions, instead of establishing distinct synaptic connections between each pair of neurons. In some implementations, equivalent lumped-element circuit simulation results can demonstrate the operation of the network. However, the idea is to replace a large number of individual interconnections between neurons with a system of a collective synaptic network that resembles or exceeds in complexity when compared to a traditional network, while any individual connection between neurons in such system exhibits synaptic behaviors in the form of spike timing and rate-dependency based learning rules. In recurrent networks with fixed numbers of interconnections between them, small-world and random networks exhibit enhanced computational power, signal-propagation speed, and synchronizability compared to an ordered network. Therefore, introducing disorder to a highly interconnected network allows us to take advantage of lower computational power consumption and higher speed in addition to the specified increase in scalability by a significant margin. Furthermore, the tight coupling between all the interconnections causes the system to directly update its configuration with changing input and output signals of any neuron, instead of updating weight of each connection separately. This results in an exponential increase in the number of non-volatile memory configurations available (some more stable than others) with an increasing number of nodes in the network. The dynamics guiding the emergent properties of such small-world or random network and the corresponding learning principles can be studied with the help of superconducting neural network elements. Furthermore, such a network made of disordered arrays of superconducting loops can be used to construct a dense recurrent neural network even with the existing well-established technologies.

In addition to the synaptic network, several other compatible network elements are presented, with circuit simulations, which together form a recurrent neural network with a hierarchical architecture, similar to a biological brain. The disclosed technology can be implemented in some embodiments to provide a design for a compatible leaky integrate-and-fire neuron with a dynamically updating threshold value. It is comprised of a large superconducting loop with a stack of Josephson junctions, with inputs occurring both in the form of direct spike trains from other neurons or as an equivalent continuous current signal corresponding to the incoming spike trains.

The feedback mechanism in the network based on some embodiments of the disclosed technology can be implemented through inductively/magnetically coupled circuits. A large number of input spike trains can be fed into the neuron through a cascade of merger circuits or through inductive/magnetic coupling into the current bias of the neuron if necessary. These various additional circuit elements are presented to underscore that a conceptually complete recurrent neural network can be built with the hierarchical architecture, using several disordered array networks. The individual recurrent networks formed by neurons and a disordered array network are in turn connected to each other through a larger hierarchical disordered array, therefore representing self-similarity at the lower and higher levels, as often found in biological brains. This approach can be followed to develop a more complex network with several additional disordered array structures at higher levels. The network based on some embodiments of the disclosed technology may include additional network components or modifications to the circuits for specific applications.

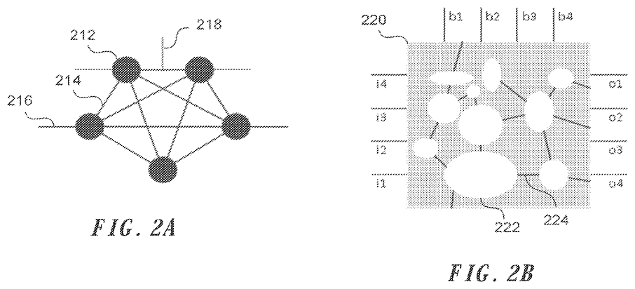

FIG. 2A shows an example of fully recurrent neural network. The fully recurrent neural network includes neurons 212, synapses 214, input and output channels 216, and a feedback 218.

FIG. 2B shows a disordered array synaptic network. In some implementations, the disordered array synaptic network includes superconducting loops 222 disposed in a superconducting material 220 and weak links 224 that form Josephson junctions.

A disordered array of superconducting loops containing Josephson junctions in them is used as a collective synaptic network that can connect several neurons together. It forms a network where each neuron is connected to every other neuron as shown in FIG. 2A, but with additional open-ended channels into it to connect to input/output neurons and to make feedback/feed-forward loop connections to synapses. Together with the feedback loops, the network is fully recurrent. A schematic of a disordered array of superconducting loops with Josephson junctions is shown in FIG. 2B. The signal propagation in these networks occurs in the form of single-flux quantum voltage pulses/spikes generated at the Josephson junctions when the current through them exceeds a critical current. The flux quanta are stored in the superconducting loops in the form of persistent loop currents. The number of flux quanta (and the corresponding persistent current) that each loop can store depends on the material and physical dimensions of the loop and therefore the resulting geometrical inductance, along with the Josephson junction parameters such as its critical current. The disordered array shown in FIG. 2B can be resolved into an equivalent lumped element circuit model for analysis as discussed in detail below. This results in dynamically changing current paths between any two nodes in the disordered array, as different junctions switch to produce single-flux quantum spikes. The stable loop currents of each state represent the memory configuration of the system.

The input and output signals, shown in FIG. 2B as i1, i2, i3, and i4 and o1, o2, o3, and o4 respectively are spiking voltage pulses while the biasing signals b1, b2, b3, and b4 are continuous but time-varying current inputs. The output voltage spikes are measured across Josephson junctions. The synaptic weight of an individual connection between any two neurons in the array is a characterization of the total current between the two corresponding nodes, which is the cumulative current from various dynamically changing paths between those two nodes. Therefore, the corresponding output spike generation across a junction depends on the input signals as well as the configuration of various loop currents from the previous state of the network. Therefore, the synaptic weight between any two nodes of the network can be calculated as shown in the equation (1) below. The memory configuration of the network is sensitive to output signals when the output spike train is coupled to biasing currents in the form of a feedback loop. The feedback/feed-forward can also occur from another synaptic network from a different hierarchical level. Changing the bias currents can change the memory/loop current configuration of the network and therefore the individual weights between any two neurons. While the feedback/feed-forward coupling to the biasing channels can enable unsupervised learning processes, the bias currents can also be updated manually to initialize the weights, or to update them when they are saturated. Further investigation is needed to develop specific programming methods to update the bias manually to interact with the emergent dynamics of the disordered system.

The dynamically changing synaptic weight between any two neurons in the network can be calculated using,

$$Synaptic weight = \frac{\# of spikes at the output neuron}{\# of spikes at the input neuron\_} \qquad Eq . ( 1 )$$

If each of the loops in the array can be designed to satisfy LI_{C}/Φ₀>1, where L is the inductance of the loop, IC is the critical current of the junction and Po is the magnetic flux quantum, then the loop can at least allow a circulating current corresponding to at least one flux quantum Φ₀ in the loop before the junction in it generates a spiking voltage pulse. More specifically, in the case of Φ₀<LI_{C}<2Φ₀ each loop can at least be in one of three configurations corresponding to +Φ₀, −Φ₀ and 0 of clockwise, anti-clockwise and zero loop currents respectively. Therefore, a disordered array with n different loops can have at least 3n different memory configurations resulting in an exponential scaling of memory capacity with increasing number of loops. This number can be even higher if some of the loops are larger and can accommodate more than a single Φ₀ in them (i.e., LI_{C}/Φ₀>2). However, any degree of symmetry in the array will result in some redundant (degenerate) configurations, where resultant weights between the nodes is identical between them. A maximum number of configurations for a given array can be achieved when the disorder is highest, with no degree of symmetry representing a random network, while any degree of symmetry represents a small-world network.

Establishing mathematical principles that guide the circuit dynamics can help understand the emergent properties of the disordered network. Such studies could also provide insight into whether specific application-related algorithms can be programmed in the form of particular small-world network array patterns. However, certain spike-timing and rate-dependency aspects of the synaptic weights in disordered networks can be demonstrated using simpler and easier to analyze arrays comprising 2 and 3 loops with arbitrarily chosen parameters. While a larger array may be more difficult to predict, various aspects of signal dynamics that occur in the simpler subset of 2 or 3 loops in the array can be understood from the following examples.

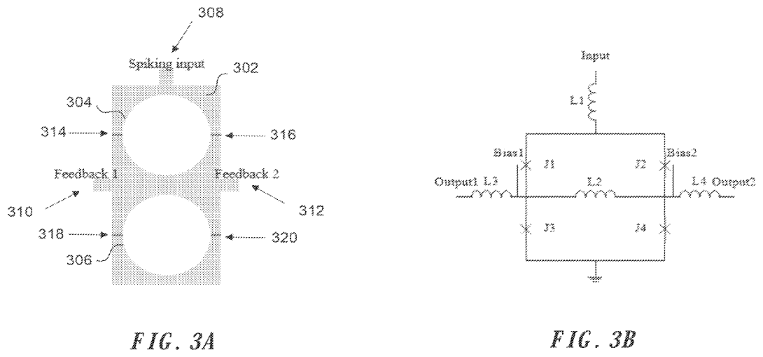

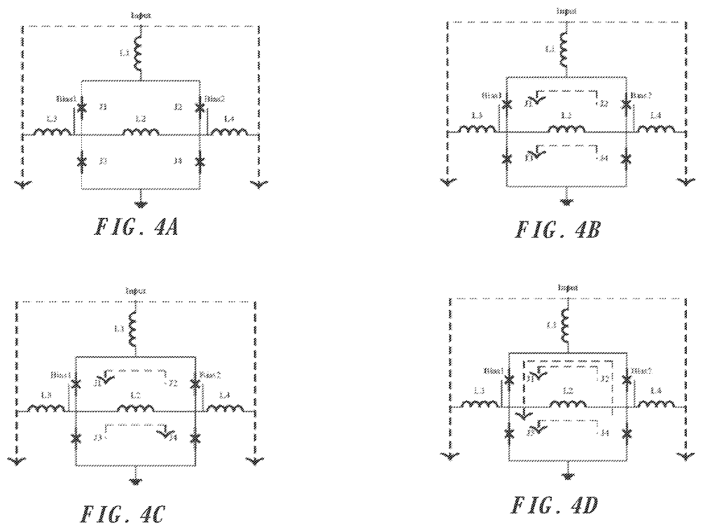

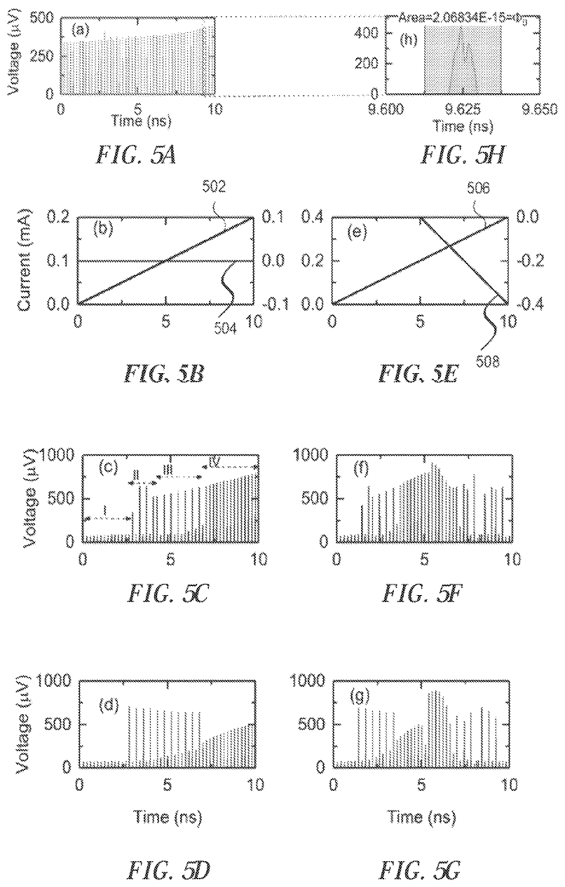

FIG. 3A shows a three-state synaptic network formed using two loops 304, 306 with one input 308, two outputs 310, 312 and two bias current channels (Feedback 1, Feedback 2). Referring to FIG. 3A, Josephson junction barriers 314, 316, 318, 320 are disposed in a superconducting material 302. FIG. 3B shows an equivalent lumped-element circuit model with junctions and inductors. Outputs (Output 1, Output 2) are voltage spikes measured across J3 and J4 as shown.

An example of synaptic network is designed to connect to 1 input neuron and 2 output neurons as shown in FIG. 3A. The network also has 2 current bias channels (Feedback 1, Feedback 2) that can be connected to feedback. The simplest form of this system is symmetric, with identical Josephson junction pairs J1, J2 and J3, J4. The inductance of the loopsis assumed to be symmetrically distributed and therefore can be characterized using lumped element inductors L1, L2, L3 as shown in FIG. 3B. The Josephson junctions define the barrier in FIG. 3B along with the superconducting material characterized by inductances. The circuit equivalent used for simulations is shown in FIG. 3B. The input excitations are chosen to represent an incoming spike train from an adjacent neuron, and the bias inputs are chosen to represent continuous current inputs from the feedback mechanism.

FIGS. 4A-4D show relative current directions corresponding to four different configurations/synaptic weights possible in the symmetric 1×2 three-state synaptic network shown in FIGS. 3A-3B.

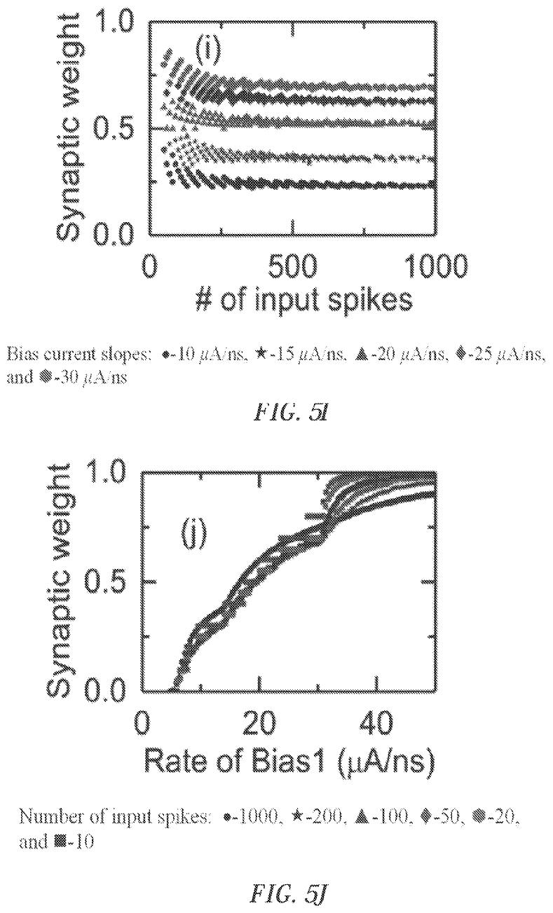

FIGS. 5A-5J shows the corresponding simulation results. The frequency of the input spike train is fixed and both the bias signals are current ramps with constant slopes as shown in FIGS. 5A, 5B, and 5E, respectively. Therefore, these excitations together represent a short time duration of the operation of the array, whereas the input and the biasing signals are expected to follow significantly complex dynamics at longer time scales. Note that the actual time scales used, i.e., the input time period of a few hundred picoseconds and the bias ramp rates of several micro-amperes per nanosecond, are not important for the operation of the circuit. However, the relative time scales such as the bias ramp rates with respect to the input frequency along with their respective magnitudes determine the synaptic weight as demonstrated in FIGS. 41 and 4J.

FIGS. 4A-4D show the various current paths and loop current components between input node and output junctions for four distinct configurations. The currents in the opposite directions that can generate negative voltage spikes are also possible, but the circuit operation corresponding to them is identical to these four configurations.

While two loops designed to satisfy 1<LI_{C}/Φ₀<2 can have 3ⁿ=9 configurations for the two loops (n=2), the symmetry in the circuit restricts the total number of distinct configurations to four, while strong coupling between the outputs makes them almost identical. The various current paths and loop current components between input node and output junctions for four distinct configurations are shown in FIGS. 4A-4D. Note that the currents in the opposite directions that can generate negative voltage spikes are also possible, but the circuit operation corresponding to them is identical to these four configurations. The circuit is simulated and the results of input, output, and bias signals as a function of time are shown in FIGS. 5A-5J.

FIGS. 5A-5J shows simulation results of the three-state synaptic network shown in FIGS. 3A and 3B. FIG. 5A shows input spike train with constant frequency and magnitude. FIGS. 5B and 5E show bias current signals. The curves 502, 506 represent current through bias 1, and the curves 504, 508 represent current through bias 2. FIGS. 5C and 5F show output spike trains measured across junction J3 of FIGS. 3A and 3B (i.e., output 1). The four different configurations corresponding to different synaptic weights are highlighted in FIG. 5C. FIGS. 5D and 5G show output spike trains measured across junction J4 of FIGS. 3A and 3B. FIG. 5H shows a magnified view of a single spike demonstrating a single-flux quantum voltage pulse. FIG. 5I shows a synaptic weight, defined as the ratio of a number of output spikes to number of input spikes, plotted as a function of the number of input spikes in 10 ns, for different values of bias current slopes. FIG. 5J shows synaptic weight, defined as the ratio of the number of output spikes to the number of input spikes in 10 ns, plotted as a function of slope of the bias current, for different numbers of input spikes.

The circuit operation is similar to that of a T flip-flop or a frequency divider, with additional, dynamically varying bias current signals that result in four different loop current states specified. Therefore, the input voltage spikes drive the incoming current through the junctions. The actual parameters and conditions used for circuit simulation are provided in supplementary material for all the simulation results presented in this patent document. However, as the circuits are disordered arrays, the choice of parameters are not critical to understand the operation of the synaptic network. Different choice of parameters produces different emergent loop configuration dynamics. However, practically plausible physical parameter values are chosen for simulations shown in FIGS. 5A-5J to demonstrate features of a spiking neural network.

When the bias currents are zero, the incoming spikes are insufficient to exceed critical currents of either of the junctions to generate an output voltage spike resulting in the configuration in FIG. 4A, and no spikes are generated at the output. This corresponds to a synaptic weight of zero. As a ramp current input with a certain slope is applied to one of the bias inputs while the other bias input is zero, the circuit cycles through its four configurations at different bias current values. Both the outputs start to generate identical spike trains as the current from constant frequency input spikes and the bias current together are sufficient to switch junctions J3 and J4 to a dynamical state generating voltage spikes. At certain current biases, as the junctions J3 and J4 together exceed their respective critical currents with each incoming spike, the output spike frequency is half that of the input frequency resulting in a synaptic weight of 0.5. This operation corresponds to the second configuration as shown in FIG. 4B and occurs between 2.5 ns and 4 ns in FIGS. 5B-5D. The circuit transitions into the third configuration at a higher bias current value where the output frequency is unchanged, but the spike generation oscillates between both the outputs as observed between 4 ns and 7 ns in FIGS. 5B-5D, corresponding to junctions J3 and J4 switching alternatively as the loop current in J3-L2-J4 cycles between +Φ₀ and −Φ₀. As the current bias further increases, both the output spike trains are identical, but a higher current bias can generate voltage spikes across both junctions J3 and J4 simultaneously with every input spike. The weight between input and both the outputs are 1 in this state as observed after 7 ns in FIGS. 5B-5D. Both the outputs are identical due to the symmetry of the system and strong coupling between the output junctions. Although there are four configurations available, there are only three useful states corresponding to weights of 0, 0.5, and 1, making it a three-state synapse.

When both the current biases are active, the system cycles through the same four memory states but the transitions occur at different times and at different current values as shown in FIGS. 5E-5G. The weight/configuration of this network, therefore, depends on the input spike timing and/or frequency, the number of input spikes, and the slopes of the bias currents. The slopes can be either positive or negative as illustrated in FIG. 5E, corresponding to either positive or negative feedback coupling.

Therefore, the memory configuration of the array is a function of two variables that are dependent on each other: the number/rate of the input spikes and the rate of change of the bias currents (i.e., the slope of the bias current signal). However, as the output signal is coupled to the bias current signal through a feedback loop, the slope of the bias current signal is proportional to the frequency of output spikes. Therefore, the synaptic weights between any two neurons are dependent on the relative timing and the rate of spikes of the input and the output signals. FIG. 5I shows the dependence between the synaptic weight calculated using Eq. (1) as the ratio between the number of output spikes measured across J3 of FIGS. 3A and 3B and the number of input spikes in a fixed time period of 10 ns. The input frequency is kept constant, while the bias current is linearly varied during this time period. The simulation results are shown for different bias current increase rates (slopes) in FIG. 5I. As evident in the results, for a fixed output frequency (or bias current slope), the synaptic weight converges to a fixed value after 500 input spikes. The number of input spikes required for convergence changes with changing input frequency. Furthermore, different choices of bias current slope result in different convergent synaptic weight, indicating that the weight can be varied between 0 and 1 with the choice of bias current slopes. This is also evident in FIG. 5J. FIG. 5J shows the dependence between synaptic weight and the slope of the bias current (equivalent to output frequency). The results for different numbers of input spikes during the fixed time interval of 10 ns (equivalent to different input frequencies) are shown. Increasing the bias current slope increases the synaptic weight non-linearly. For the given set of input frequencies seen in FIG. 5J, thresholds appear at certain bias current frequencies, such as at 15 μA/ns and 30 μA/ns where the synaptic weight appears to saturate as constant frequency input spikes are applied. The input frequency determines the resolution of weights that can be accessed between 0 and 1. FIGS. 5I-5J highlight the spike-timing and rate dependencies of input and output signals on the synaptic weight.

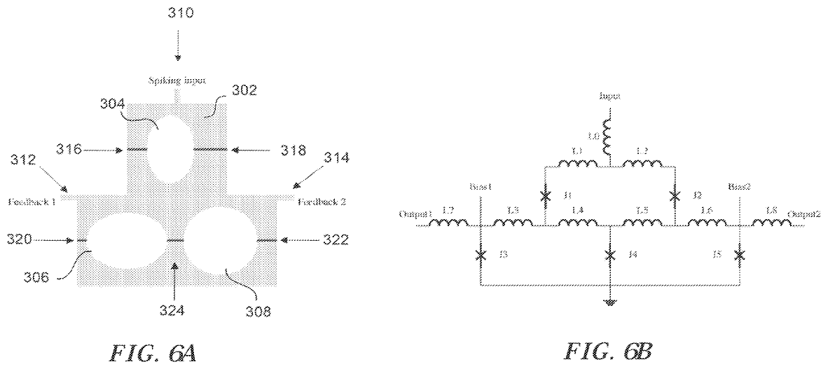

FIG. 6A shows 1×2 three-loop disordered array synaptic network with two feedback terminals. Referring to FIG. 6A, the 1×2 three-loop disordered array synaptic network includes three superconducting loops 604, 606, 608 formed in a superconducting material 602, Josephson junction barriers 616, 618, 620, 622, 624 connected to the superconducting loops 604, 606, 608. The 1×2 three-loop disordered array synaptic network also includes one input channel 610, two output channels 612, 614, and two bias current channels (Feedback 1, Feedback 2). FIG. 6B shows equivalent lumped-element circuit model with junctions and inductors. The output voltage spikes are measured across junctions J3 and J5. The circuit is completely disordered with no two junctions or inductors identical to each other.

The three-state synaptic network describing two loops is a highly constrained and symmetric (degenerate) system and was chosen to demonstrate the basic dynamics of a disordered array even though the symmetry resulted in degenerate memory configurations. Even this three loop geometry offers more options and complexities. Introducing some disorder in the system in the form of asymmetric geometry exponentially increases the number of configurations/states available, thereby transforming it to a complex system, while exhibiting similar time and rate-dependent dynamics with respect to input signals and output signals through feedback. A complex 3-loop disordered array system is chosen to demonstrate the dynamics of a network with 1 input and 2 outputs as shown in FIG. 6A. In the equivalent circuit shown in FIG. 6B, no two junctions are identical to each other. Furthermore, the inductance is asymmetrically distributed around loops. The inductor values and Josephson junction parameters are arbitrarily chosen, with a restriction to only allow up to 1 single-flux quantum in each of the loops. The actual parameters used in the simulation results are provided in the supplementary material. The circuit can be in up to 33=27 different configurations, each of them resulting in different weights between the input and either of the two output neurons, which range from 0 to 1. The weight dynamically changes with changing input frequency or the rate of change of any of the bias currents (equivalent to the feedback corresponding to respective output frequencies).

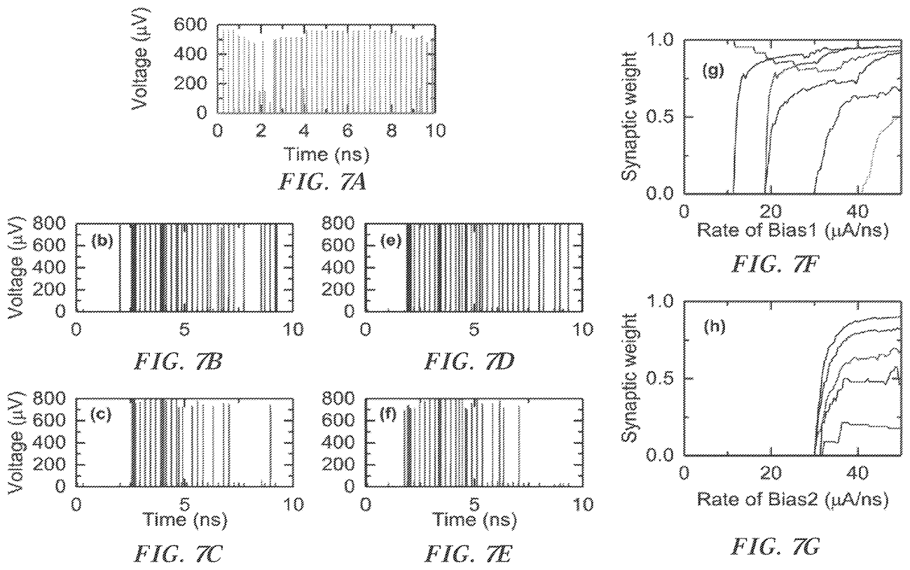

FIGS. 7A-7H show simulation results of the synaptic network shown in FIGS. 6A and 6B. FIG. 7A shows constant frequency spiking input from an adjacent neuron. FIG. 7B shows output spikes measured across an outer junction of the first output loop with feedback slopes of 20 μA/s and 0 μA/s. FIG. 7C shows output spikes measured across an outer junction of the second output loop with a feedback slope of 20 μA/s and 0 μA/s. FIG. 7D shows output spikes measured across an outer junction of the first output loop with feedback slopes of 20 μA/s and—10 μA/s. FIG. 7E shows output spikes measured across an outer junction of the second output loop with a feedback slope of 20 μA/s and—10 μA/s. FIG. 7F shows synaptic weight between output 1 and input with constant input frequency as a function of rate of change of feedback 1 at different values of rate of change of feedback 2. FIG. 7G shows synaptic weight between output 1 and input at different input frequencies as a function of rate of change of feedback 1 at a constant rate of change of feedback 2.

Two different cases with different combinations of bias signals (i.e., different ramp rates) are simulated to demonstrate this aspect. The input spike frequency is kept constant, and the results of output spikes are presented in FIGS. 7A-7G. The resulting output spike trains demonstrate voltage spikes with the timing between them varying according to the bias current signals. A constant frequency spike train shown in FIG. 7A is applied to the input terminal. The two output spike trains are plotted for two different biasing conditions in FIGS. 7B and 7C and 7D and 7E, respectively. The output spike trains are significantly more complex for the given deterministic input spike train and, therefore, are a result of the disordered coupling as well as the biasing conditions. Note that an inhibitory output can generate a decreasing or a negative bias current. As the physical parameters of the circuit remain unchanged, a correlated set of relations can be drawn between the synaptic weight and the input/output signals. To illustrate this, the synaptic weights are plotted as a function of slope of the bias current with constant input frequencies in FIGS. 7F and 7G. Different curves in the plot represent different input frequencies. Bias 1/feedback 1 is varied with bias 2 constant in FIG. 7F while bias 2/feedback 2 is varied with Bias1 constant in FIG. 7G. Similar to the results observed in the three-state synaptic network in FIGS. 5A-5J, the weight is zero below a threshold value of bias current slope. This threshold is dependent on the input frequency as evident in FIGS. 7F and 7G. Above the threshold, the weight changes with changing current slopes until a saturation value is reached, which is also dependent on the input frequency. While the actual dynamics are significantly complex to understand in detail, the emergent phenomenon exhibits spike timing and rate dependency of input and output (through feedback) on the synaptic weight. Additionally, the resulting synaptic weights are dependent on the previous state of the system. Note that the assumption here is that the parameters are chosen to satisfy 1<LI_{C}/Φ₀<2. Relaxing those conditions would result in more than 27 configurations.

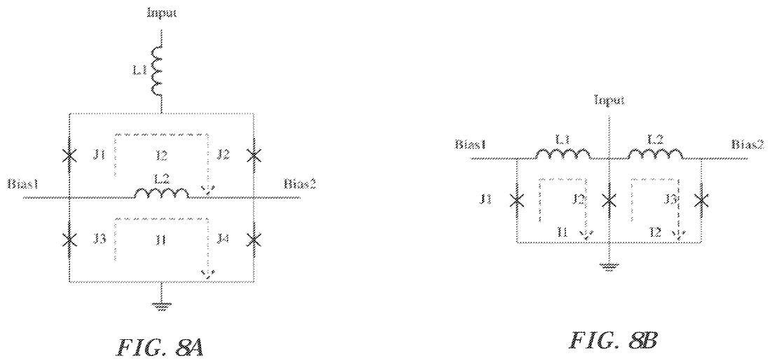

FIGS. 8A and 8B show schematics representing two different types of loop interactions that can occur in a large disordered-array. FIG. 8A shows two loops coupled to each other through an inductive element. FIG. 8B shows two loops coupled to each other through a Josephson junction.

The number of configurations available increases exponentially with an increasing number of loops. Therefore, it is difficult and not too instructive to determine the behavior of such systems with a similar circuit analysis performed for smaller arrays. Nevertheless, the circuit dynamics established so far can be expanded to understand interactions between any two adjacent loops that are part of a larger array. Two different variations of coupling can occur between any two such adjacent loops as shown in FIGS. 8A and 8B. In the first case, the loops are coupled through an inductor as shown in FIG. 8A, whereas in the second case, the loops are coupled through a Josephson junction as shown in FIG. 8B. In both cases, the configuration of the network (i.e., synaptic weight between any two nodes) changes when the loop currents change. Changes in loop currents occur when one or more of the junctions switch to a dynamic state, generating a single-flux quantum voltage pulse, following the current through them exceeding their respective critical currents. In other words, any current path between the neurons changes when one of the junctions in the path switches, resulting in a change in weight. Output spikes are produced when the current across the output junctions exceeds its critical current. Therefore, the interaction between the loops can be understood through the loop currents as a function of time and their transitions as the output frequency changes.

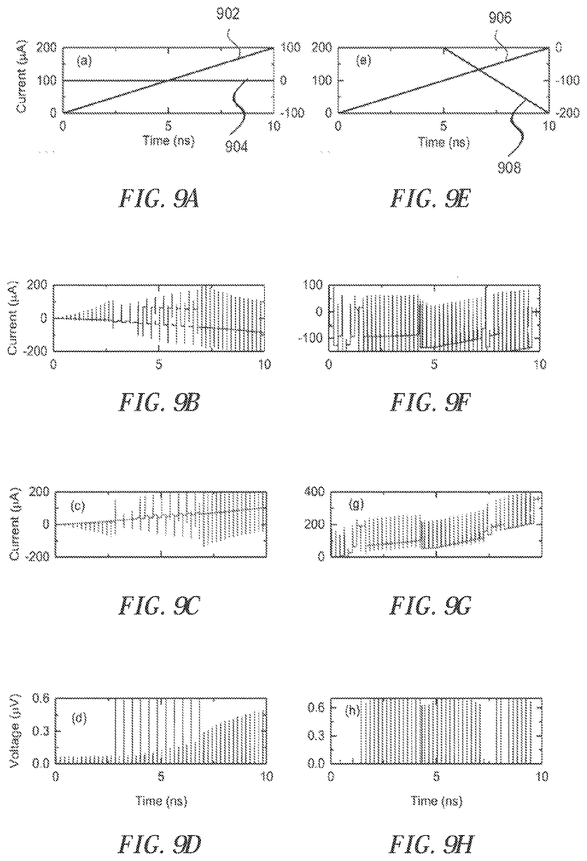

FIGS. 9A-9H show simulation results of the two loop circuits shown in FIGS. 8A and 8B. FIGS. 9A and 9E show bias currents applied to the circuits from FIGS. 8A and 8B, respectively. The curves 902, 906 represent current through bias 1, and the curves 904, 908 represent current through bias 2.

When two adjacent loops have an inductor in common as shown in FIG. 8A, the circuit operates similar to that of a three-state synaptic network of FIGS. 3A and 3B. The simulation results of loop currents along with the output voltage spike train measured across junction J4 as a function of time are shown in FIGS. 9A-9D for the specified bias current signals. The circuit operates in the mode that is identical to that shown in FIG. 4A. Transient spiking currents are observed at regular intervals corresponding to each input voltage spike because the simulations performed are using transient circuit analysis. However, the steady-state currents between these spikes are indicative of the memory configuration of the array. FIGS. 9B and 9C are the loop currents corresponding to loops J1-L1-L2-J2 and J3-L3-J4, respectively. Note that the current on one of the biasing terminals is steadily increasing, resulting in a corresponding increase in the steady-state loop currents. The circuit is subjected to the same four different configurations as that of FIGS. 5C and 5D. The loop currents are subjected to different interactions during these four configurations as they interact through the common inductor L3. When the output voltage is zero, the loop currents steadily increase or decrease until the loop current is sufficient to switch one of the junctions J3 or J4. As the bias current increases further, the output voltage generates a spike at every alternative input spike. The loop currents in J1-L1-L2-J2 and J3-L3-J4 cycle between +Φ₀ and −Φ₀. The voltages across each of the junctions in these four states are shown in the supplementary material to further support the analysis. Initially, the loop currents are opposite to each other, acting together at L3. At a higher bias current, the loop currents are identical, therefore acting against each other through L3 as seen in FIGS. 9B and 9C between 2.5 ns and 7 ns. In an asymmetric circuit, these two different configurations result in two different sets of weights. The cycling between states stops as the bias current increases further resulting in switching of all four junctions. Any further increase in bias current will result in a higher output frequency irrespective of the input signal. Therefore, when loops are coupled through an inductor, the relative cycling of individual loop currents between +Φ₀ and −Φ₀ can result in different weights, while switching of the junctions changes the number of flux quanta Do in the array.

The second type of coupling between the loops can occur through a Josephson junction as shown in FIG. 8B. The simulation results of loop currents and the output voltage are shown in FIGS. 9E-9H as a function of time for the given bias currents. In this array, the loop currents do not cycle between states with each input voltage spike, but abruptly switch to different values as one of the junctions switch. Switching of either J1 or J3 can add or remove a flux quantum Φ₀ to the array, while switching of J2 results in a change in weight by changing the interaction between the loop currents in both the loops. The corresponding voltages between each of the junctions in this configuration are provided in the supplementary material.

Therefore, the parameters of a large disordered-array network can be described as shown in Eq. (2), with the relation between any two neurons in the network defined by the input i1, i2, . . . and output signals o1, o2, . . . , along with the physical parameters c1, c2, . . . that are dependent on the coupling inductors and junctions between any two loops. Such a relationship can be used to characterize synaptic weights to physical parameters c1, c2, . . . for given inputs and outputs.

$$[ \begin{matrix}i 1 \\ i 2 \\ …\end{matrix} ] = [ \begin{matrix}c 1 & c 2 & … \\ c 3 & c 4 & … \\ … & … & …\end{matrix} ] = [ \begin{matrix}o 1 \\ o 2 \\ …\end{matrix} ] . \qquad Eq . ( 2 )$$

Identifying the coupling constants as shown in Eq. (2) does not imply that the weights can be programmed in a deterministic way. This is because the inputs i1, i2, . . . and outputs o1, o2, . . . are coupled to each other through feedback, and therefore their values are dependent on the previous memory state of the system. Furthermore, in the two and three loop synaptic array examples discussed in FIGS. 4A-4D and 8A and 8B, it is clear that there is an upper limit to bias current, above which all the junctions in the circuit will be in the normal state (not shown in the simulation results). The feedback mechanism can be designed appropriately to only allow bias currents below this upper limit.

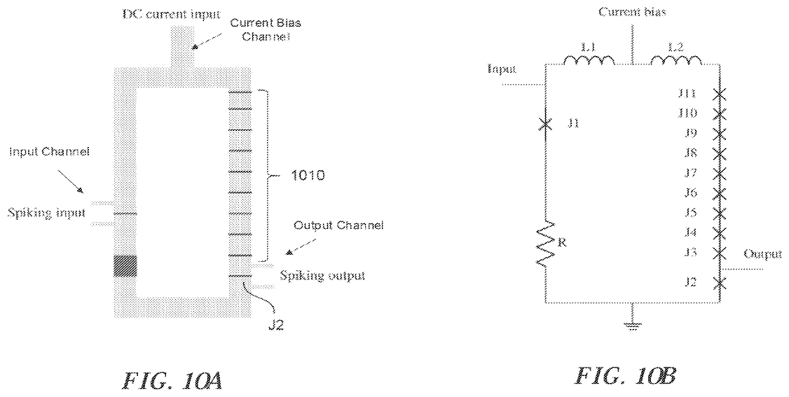

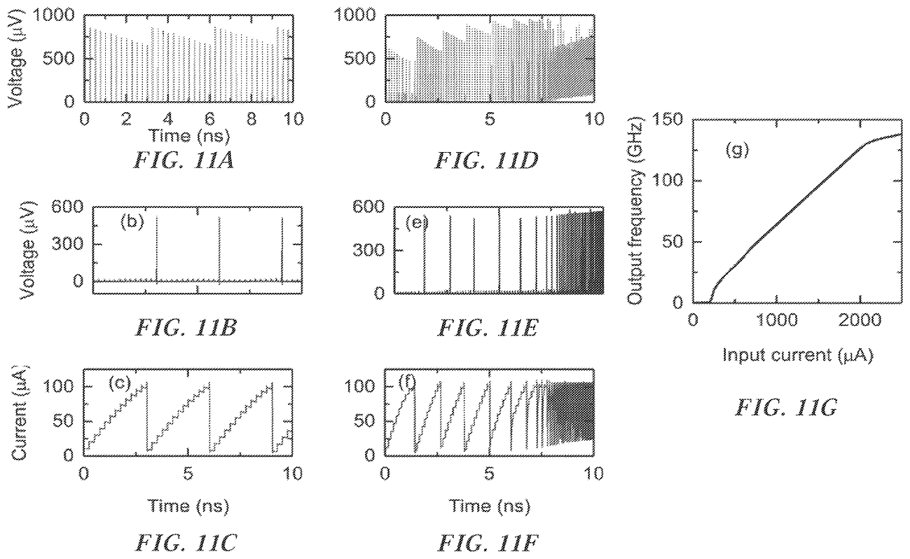

FIGS. 10A and 10B show leaky integrate-and-fire neuron circuit schematic. Input signal (Spiking input) represents spike trains received from other neurons/disordered arrays. Current bias represents integrated feedback and/or feed-forward signals. Output spike train is measured across junction J2.

FIG. 11A shows input spike train with constant magnitude and frequency. FIG. 11B shows output spike firing after the input signal reaches a threshold, for a given constant current bias. The current bias value defines the threshold. FIG. 11C shows loop current representing the total signal accumulated in the neuron. The currents reset to a “rest” value after the neuron reaches the threshold and fires. FIG. 11D shows varying frequency input signal obtained by applying a ramp current of a constant slope to the current bias. FIG. 11E shows output spike train corresponding to input as in FIG. 11D. FIG. 11F shows loop current accumulated in the neuron showing dependency on input frequency. FIG. 11G shows input current bias vs. output frequency. The threshold varies with circuit parameters.
LI_{C}/Φ₀, where L is the inductance of the loop (i.e., L=L1+L2 in FIG. 10B), I_{C} is the critical current of the junctions in the identical junction stack, and Phi₀ is the magnetic flux quantum given by 2.5×10⁻¹⁵ Wb. When the loop current reaches a threshold, the junctions in the stack develop single-flux quantum voltage spikes. Therefore, the output spike train can be measured across one of the junctions in the stack as shown. Switching all the junctions in the stack results in a decrease in the persistent current in the integration loop to a resting potential uᵣₑₛₜ. The simulation results of the incoming spikes of constant frequency, output spikes, and the loop current are shown in FIGS. 11A-11C, respectively. A small resistor R is added to the superconducting loop to allow the loop current to decay with a time constant of

$$τ = \frac{L}{R} ,$$

therefore exhibiting a leaky integrate-and-fire aspect. The resistor, therefore, allows us to decrease the time constants of the current loop to the time scale of the input signals. As shown in FIGS. 11A-11C, the circuit produces a spiking output when the loop current reaches a threshold value when a constant bias current as a constant frequency input spiking signal is applied. The operation of this design closely emulates a leaky integrate-and-fire model, which is described by

$$τ \frac{d}{dt} u = - ( u - {u}_{rest} ) + RI ( t ) . \qquad Eq . ( 3 )$$

The neuron fires and resets to resting potential when u(t)=v, where u(t) is the loop current and v is the threshold defined by LI_{C}/Φ₀.

The threshold, i.e., the number of incoming spikes needed for the neuron to fire, can be varied through a bias current/feedback loop as shown in FIGS. 11D-11F. A linearly ramping current is applied to the bias without a spiking input. FIG. 11E shows that the threshold and the resting potential decrease as the current bias is increased, resulting in fewer input spikes required to fire the neuron. Therefore, when the bias current terminal is coupled to a positive feedback signal from the disordered array network, the neuron can be made to fire more readily and vice versa. The actual dynamics of the feedback/feed-forward signals can be a result of immediate output signals or signals from a different hierarchical level of the neural network through a feedback mechanism, similar to the mechanism for the synaptic network. Additionally, the current bias channel can also be used to integrate spike trains from a large number of neurons/synaptic networks through a similar mechanism as that of feedback. Furthermore, the loop current magnitude (i.e., either resulting from the spiking input or the bias current) vs. the output frequency resembles that of the ideal leaky integrate-and-fire model described by Eq. (3). The simulated input current vs. output frequency is shown in FIG. 11G. Therefore, this model circuit demonstrates the operation of a leaky integrate-and-fire model that is compatible with the disordered array synaptic network.

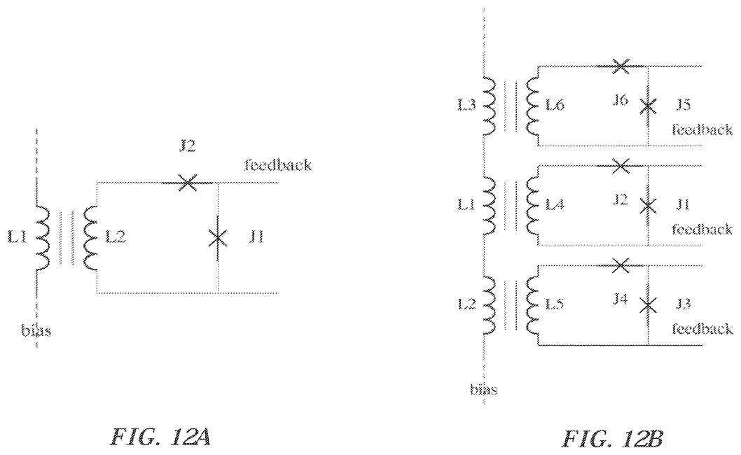

FIGS. 12A and 12B show feedback mechanisms. FIG. 12A shows a feedback circuit to convert single-flux quantum pulses into current bias with a similar mechanism. FIG. 12B shows several feedback connections can be made to a single bias line.

One of the important aspects of the various circuits introduced in the implementations discussed above is the feedback mechanism. Continuous and linearly increasing or decreasing ramp currents are chosen to emulate a simplified response from these feedback connections. In some implementations, the mechanism to convert an output spike train into a continuous bias current is presented. Nevertheless, this circuit is suitable to convert an output spike train into a continuous current signal, the slope of which is proportional to the frequency of the spike train. The circuit for feedback is shown in FIGS. 12A and 12B. When a spiking input of constant frequency is applied across junction J1 of FIG. 12A, a circulating current is added to the loop comprising J1-J2-L2. This current loop is inductively coupled to the larger current loop that goes through the bias current terminal and into the disordered array network. As the circulating current in the loop J1-J2-L2 increases, the current through the inductor L1 and, therefore, the bias current terminal increases. An upper limit to the bias current exists in this mechanism that is set by the inductor L2 at which the bias current saturates. The corresponding simulation results are shown in FIGS. 12A and 12B. The inductive coupling to the bias line can either be positive or negative, representing an excitatory or inhibitory input, respectively. As evident from the synaptic network simulations, the bias currents can only be increased up to a certain value before reaching the maximum synaptic weight of 1. Increasing the bias currents beyond certain value results in all the Josephson junctions in the array switching into the normal state without further evolution of the memory configurations. Therefore, the saturation values of the feedback current loops must be designed to limit bias currents from driving the disordered array into a saturated state.

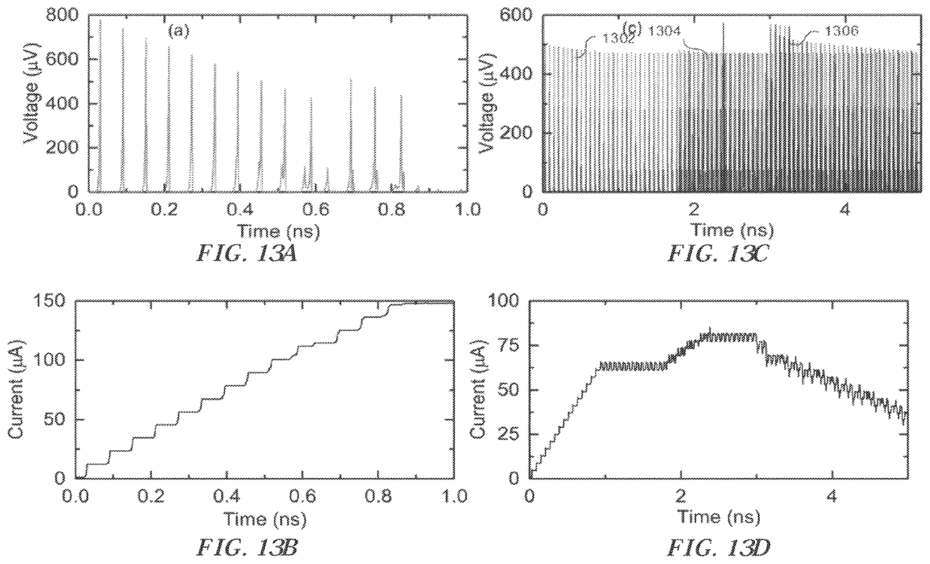

FIGS. 13A-13D show simulation results of feedback circuits shown in FIGS. 11A-11G. FIG. 13A shows spike train from output applied to J1 in FIG. 12A. FIG. 13B shows current bias through LI in FIG. 12A that can be applied to the disordered array. FIG. 13C shows spike trains applied to different hierarchical feedback loops through J1, J3, and J5, respectively. Spikes 1302 represent signal applied at J1, spikes 1304 represent signal applied at J3, and spikes 1306 represent signal applied at J5. FIG. 13D shows total accumulated current on the bias line through inductors L1, L2, and L3 due to signals applied as shown in FIG. 13C.

A single bias line can be used to integrate feedback inputs from a large number of spike trains incoming from various channels in the network from different hierarchical levels of the recurrent neural network. The schematic of this aspect is demonstrated in FIG. 12B and the corresponding simulations results are shown in FIGS. 13C and 13D. Three different spike trains are applied to feedback loops across J1, J2, and J3, respectively as shown in FIG. 13C. The inductive coupling to the inductor L3 in the biasing loop is in the opposite direction to that of the other two inductors resulting in the negative bias current. Initially, only one of the feedback spike trains (across L1) is active causing the total bias current to linearly increase until it reached saturation at 2 ns. When the second spike train (across L2) is active, the bias current further increases until it reaches a new saturation value. Note that the spike train across L1 is active during this period. Adding a negatively coupled spike train to this bias loop through L3 allows the bias current to decrease resulting in a complex mechanism to update the total bias current as shown in FIG. 13D. The bias currents can also be updated manually by injecting current through a separate inductor in order to update the weights.

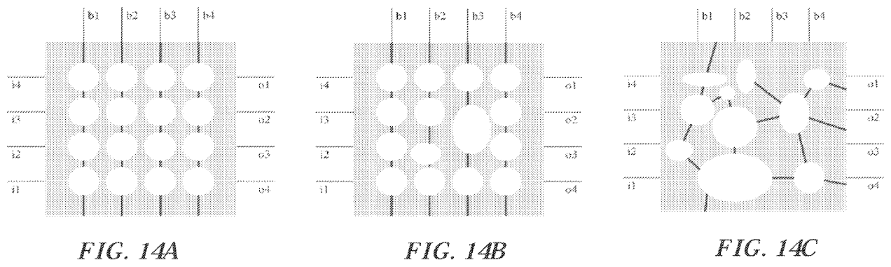

FIG. 14A shows an example of regular network. FIG. 14B shows an example of small-world network. FIG. 14C shows an example of random disordered array synaptic network.

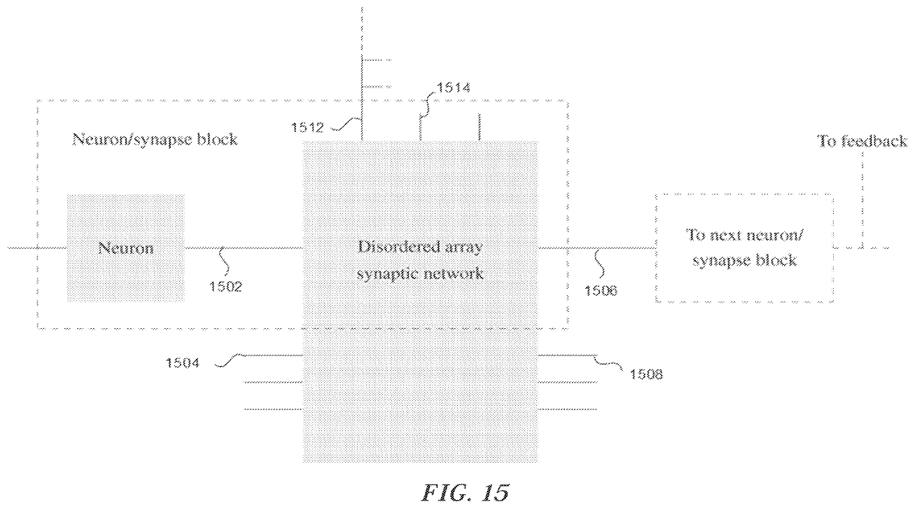

FIG. 15 shows neural network schematic illustrating feedback connections for a hierarchical architecture. Lines 1502, 1504, 1506, 1508 represent connections from/to neurons, and lines 1512, 1514 represent feedback connections. Feedback from multiple hierarchical levels can be coupled to each bias line on disordered arrays.

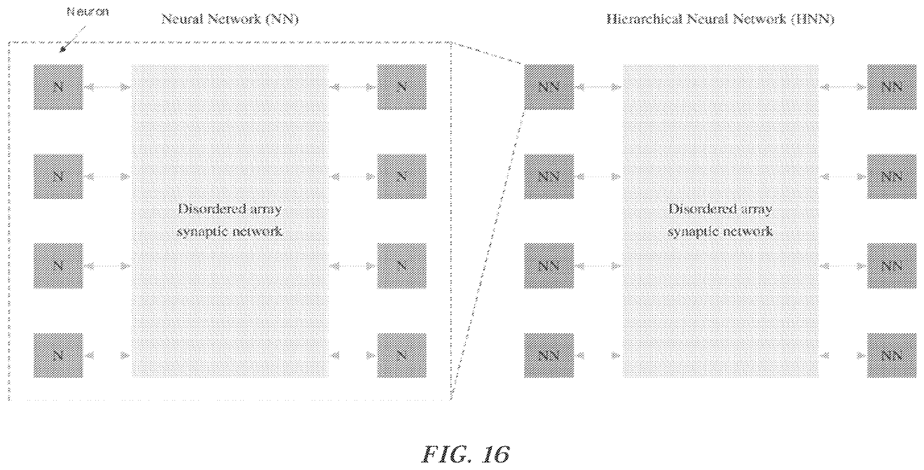

FIG. 16 shows a neural network schematic for the hierarchical architecture. The schematic on the left represents individual neurons connected to each other through a disordered array. The schematic on the right represents individual networks (may be viewed as corresponding to different functions) on the left connected to each other through a hierarchical disordered array.

As mentioned above, the disordered array synaptic networks and the building blocks developed around them can be integrated together in a way to design fully connected and recurrent neural networks with hierarchical architecture for unsupervised learning. Any degree of symmetry in the disordered array results in degenerate memory configurations resembling a small-world network. The disorder can be varied to obtain small-world and random networks to take advantage of the collective emergent properties, as shown in FIGS. 14A-14C. The schematic of a fully recurrent neural network at the lowest level is shown in FIG. 15. The input nodes to the disordered array can be connected to the loop neurons, while the outputs can be coupled to the bias current terminals of the array through a feedback mechanism. The additional input and output nodes are open-ended that can be connected to other recurrent networks. Therefore, several of these neural networks can be combined together through a hierarchical disordered array with additional feedback connections arising from that array coupled to bias terminals of the lower level disordered arrays as shown in FIG. 16. Additionally, this architecture allows scaling the recurrent neural networks with self-similarity at the lowest and highest levels similar to that of a biological brain. However, the emergent dynamics of such a network must be further investigated to determine the programming methods to update the weights as well as to design specific disordered patterns optimized for particular applications.

The organization of biological brain networks can be classified into structural and functional motifs, where the brain networks develop by maximizing the functional motifs available for a small repertoire of structural motifs as allowed by evolutionary rules. Furthermore, the structural motifs are predominantly small-world networks that support a large number of complex metastable states. The disordered array networks, therefore, allow flexibility to represent structural motifs that are designed for specific functionality. Several such distinct recurrent networks can be combined together in a hierarchical network to achieve a higher level functional motif operation.

In addition, this system represents a recurrent network with an architecture of a hierarchy of loops, ranging from individual loop currents in a disordered array to a large loop current through the feedback network. The integration of information across a wide range of spatial and temporal scales can be constructed using disordered array networks as summarized in FIGS. 15 and 16. Such a highly scalable network can be used to develop a complex system that can reconfigure itself in response to the inputs analogous to a biological brain network.

The disclosed technology can be implemented in some embodiments to provide a new approach to neuromorphic computing architecture using collective synaptic networks implementing disordered arrays. In some implementations, superconducting disordered array loops can be used to demonstrate the architecture. Equivalent lumped-element circuit simulations are used to illustrate complex dynamics of individual elements of such networks. The simulation results are shown for a short time duration of operation of the network with simplified excitation conditions, as the actual operation of these networks is significantly more complex. Additionally, the disclosed technology can be implemented in some embodiments to provide components such as leaky integrate-and-fire neuron and feedback that can be used to construct a recurrent neural network together with disordered arrays. Furthermore, in some embodiments of the disclosed technology, a large complex neural network with the hierarchical architecture that is similar to a biological brain can be constructed from the individual recurrent networks. However, the superconducting loops is not limited to this architecture and this disordered array approach can also be used with other hardware mechanisms of various materials that emulate neuron and synapse-like behavior. This can be achieved by creating a disordered array of coupled synapses in the network to create a complex dynamical system with a significantly larger number of states than individual synaptic connections between neurons. However, the introduced superconducting circuits can be used to develop the mathematical basis to further understand emergent phenomena to aid development of networks for practical applications.

Some embodiments of the disclosed technology can significantly improve scalability of a neural network by replacing a large number of separate interconnections between neurons with a considerably smaller disordered array. Additionally, this high degree of inter-connectivity through a small-world network increases the synchronizability, therefore enabling faster learning. Additionally, these circuits can naturally emulate spiking features of biological brains at high operating speeds up to hundreds of GHz while dissipating energies of the order of a few aJ/spike.

As the synaptic network is based on disordered arrays of loops with Josephson junctions, the exact parameters used in circuits for simulation are not relevant to understand these systems. Each different set of parameters can generate a unique set of outputs and could provide access to a different set of states. The parameters that can be used to generate the various simulations shown in this patent document will be provided below. Additionally, the voltages across different junctions corresponding to various simulations shown are also provided to facilitate better understanding of the dynamics of the circuits provided.

### Symmetric 3-State Synaptic Network

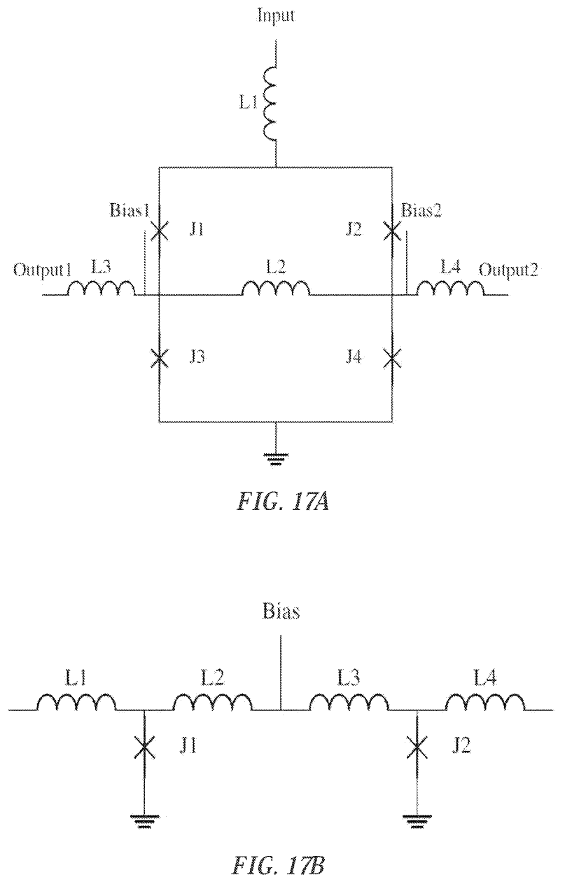

FIG. 17A shows 3-state synaptic network with 1 input, 2 outputs and 2 bias current channels. Outputs are voltage spikes measured across J3 and J4. FIG. 17B shows a Josephson transmission line cell used at input, output and intermediate cells in all the circuits to verify that the designed cells can operate with any other circuits.

The binary synaptic network based on some embodiments of the disclosed technology is similar in operation to a T-flip flop or a frequency divider circuit, when biased appropriately. But when the bias currents are dynamically changing as a response to a feedback current, then in turn the circuit can exhibit various different output configurations as described in FIGS. 4A-4D and 5A-5J.

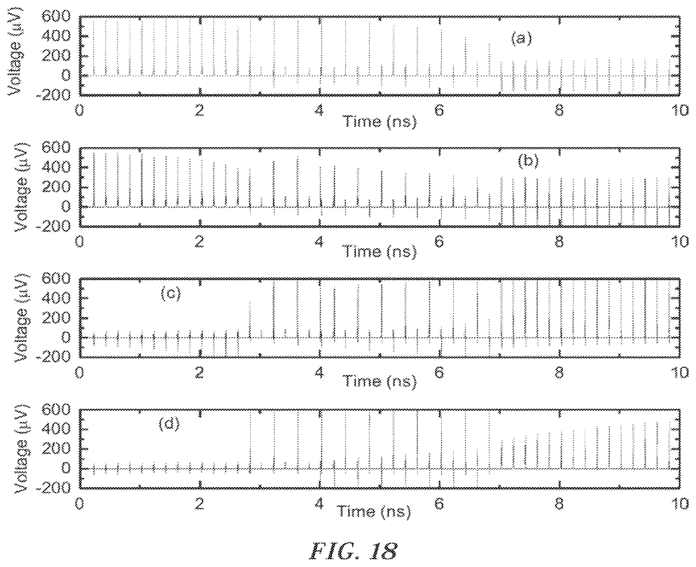

FIG. 18 shows voltage drop across each of the junctions of FIG. 17A with the bias conditions of FIG. 5B. FIG. 18 (a) shows voltage across J1, FIG. 18 (b) shows voltage across J2, FIG. 18 (c) shows voltage across J3, and FIG. 18 (d) shows voltage across J4.

The parameters used for the circuit are based on Nb-based circuits. A gap voltage (2Δ) of 2.8 mV has been used for all junctions. Junctions J1 and J2 have a critical current of 100 μA, while J3 and J4 have a critical current of 140 μA. A shunt resistance of 4Ω is used with every junction to ensure that the damping parameter

$${β}_{C} = \frac{2 e}{ℏ} {I}_{C} {R}^{2} C \leq 1.$$

Inductors L1 has a value of 3.7 pH and L2 has a value of 20.8 pH and inductors L3 and L4 are chosen to be 10 pH. Single-flux quantum voltage pulses are injected at the input through a short section of Josephson transmission line shown in FIG. 17B. Junctions J1 and J2 of critical current 140 μA are used, with a constant Bias current of 200 μA. Inductor L1 has a value 10 pH, L2 and L3 have 5 pH each, and L4 has a value of 2.5 pH. A pulse current input of 325 μA with a pulse period of 20 ps is fed into the input of the Josephson transmission line to generate single-flux-quantum voltage spikes as input to the binary synaptic network, with a regular interval of 200 ps. This is used as a spiking voltage input of fixed frequency with changing bias currents to demonstrate the operation of the synaptic network. This Josephson transmission line cell is used for the input to all the other synaptic network and neuron circuits implemented based on some embodiments of the disclosed technology. This is done to ensure that the circuit can operate in conjunction with any other circuit according to the established behavior, i.e., the Josephson transmission line may be replaced with any other circuit presented, such as neuron, feedback circuit etc., without affecting the behavior of the circuit of interest.

The output currents from a synaptic network can be fed into the next cell through inductors of appropriate size with an inductance value satisfying the condition LI_{C}(Φ₀<1.

To provide additional insight into the operation of the binary synaptic network, the voltages across each of the junctions J1, J2, J3, and J4, for one of the biasing conditions corresponding to FIG. 5B, are presented in the FIG. 18 below. Voltages across junctions J3 and J4 are discussed above as the output voltages. FIG. 18 below includes voltages across J1 and J2 along with the output voltages across J3 and J4. The input current entering the circuit corresponding to every voltage spike gets divided between the two paths through J1 and J2 into the loop J3-J3-J4, contributing to the circulating current in the loop. The direction of the circulating current is determined by several factors including the bias currents Bias1 and Bias2, along with the input current. The input current contributes to an anti-clockwise current component when it takes the path J1, while it contributes to a clock-wise current component when it takes the path J2. It contributes equally to both components when current is divided equally between the two paths, and the effective circulating current direction depends on the bias current magnitudes. Therefore, when one of the junctions J1 or J2 switches to a normal state, the circulating current components change accordingly. In an asymmetric circuit, i.e., when the junctions and inductors are of different sizes, the circuit can behave in a chaotic manner switching between the nine possible states (i.e., 3ⁿ=9, with n number of loops and each loop with 3 possible states of +Φ₀, −Φ₀ and 0). The state of the circulating currents (or flux) in both the loops together define the synaptic weight between any two nodes.

### Asymmetric 3 Loop 1×2 Synaptic Network

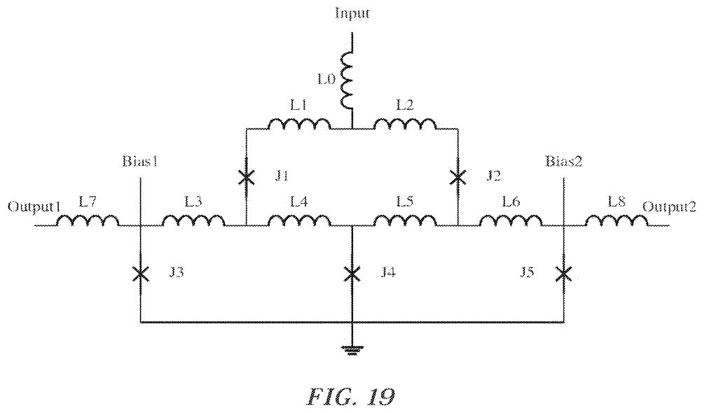

FIG. 19 shows 3-loop shows 1×2 disordered array synaptic network. The output voltage spikes are measured across junctions J3 and J5. The circuit is completely disordered with no two junctions or inductors identical to each other.

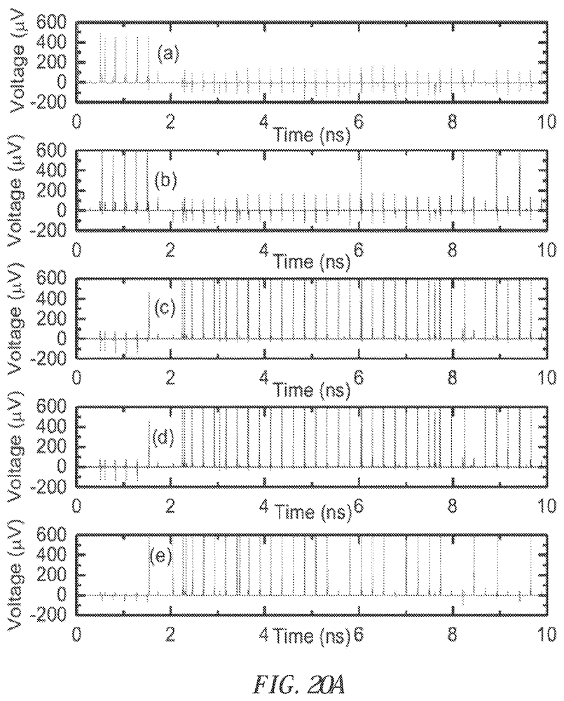

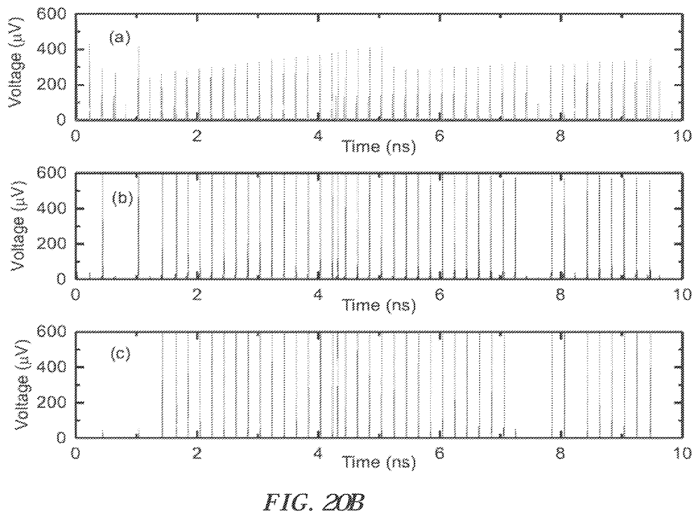

The parameters used for the circuit shown in FIGS. 6A-6B are chosen to represent a circuit operation when there are more than 2 loops in the disordered array. Furthermore, the parameter values are also chosen to represent an asymmetric system with all the junctions and inductors in the circuit are different from each other. Such a system is expected to exhibit the maximum number of available memory configurations in the system. The circuit is shown in FIG. 19. The critical currents of each of the junctions are given below: Critical current of J1-100 μA, J2-140 μA, J3-120 μA, J4-160 μA and J5-110 μA. The values of inductances are: L0-3.7 pH, L1-3 pH, L2-5 pH, L3-48 pH, L4-12 pH, L5-24 pH, L6-20 pH. The operation of this circuit can be significantly complicated when compared to a 2-loop array and its behavior is sensitive to input and bias signals. Voltage drops across all the junctions are provided in FIG. 20 for one of the biasing conditions that is shown in FIG. 7B. Depending on the bias current and the input spike configuration, the current from the input can flow into either of the outputs. When these currents are sufficient to switch either of the output junctions J3 or J5, output spikes are produced. The current paths change whenever one of the junctions in the path switches, therefore updating the synaptic weights.

FIG. 20A shows voltage drop across each of the junctions of FIG. 19 with the bias conditions of FIG. 7B: (a) Voltage across J1; (b) Voltage across J2; (c) Voltage across J3; (d) Voltage across J4; and (e) Voltage across J5.

### Large Disordered Array Networks

A system that is larger than 3 loops can be expected to have similar circuit dynamics as established in 2 loop and 3 loop systems, with current paths and loop currents representing the memory state of the system, which is in turn dependent on the input and feedback signals from all the neurons that are connected to the network.

Therefore, two different types of loop interactions that can occur in any large array are discussed. The parameters for the corresponding circuits from FIG. 8A are exactly identical to that of FIG. 16, whereas in FIG. 8B, junctions J1, J2 and J3 have a critical current of 140 μA and the inductance L1 and L2 are both 20 pH. The voltages across junctions in FIG. 8A are same as that shown here in FIG. 18.

FIG. 20B shows voltage drop across each of the junctions of FIG. 8B with the bias conditions of FIG. 9E: (a) Voltage across J1; (b) Voltage across J2; and (c) Voltage across J3.

Superconducting Disordered Neural Networks for Neuromorphic Processing with Fluxons

In superconductors, magnetic fields are quantized into discrete fluxons (flux quanta Φ₀), made of microscopic circulating supercurrents. The disclosed technology can be implemented in some embodiments to provide a multi-terminal synapse network comprising a disordered array of superconducting loops with Josephson junctions. The loops can trap fluxons defining memory while the junctions allow their movement between loops. Dynamics of fluxons through such a disordered system through a complex re-configurable energy landscape represents brain-like spiking information flow. The disclosed technology can be implemented in some embodiments to provide a 3-loop network using YBa₂Cu₃O_{7-δ} based superconducting loops and Josephson junctions, that exhibits stable memory configurations of trapped flux in loops that determine the rate of flow of fluxons through synaptic connections. The memory states are in turn affected by the applied input signals but can also be externally configured electrically through control current/feedback terminals. These results establish a novel, biologically similar architectural approach to neuromorphic computing that is scalable, while dissipating energy of atto Joules/spike.

The disclosed technology can be implemented in some embodiments to provide a novel disordered superconducting loop based neural network.

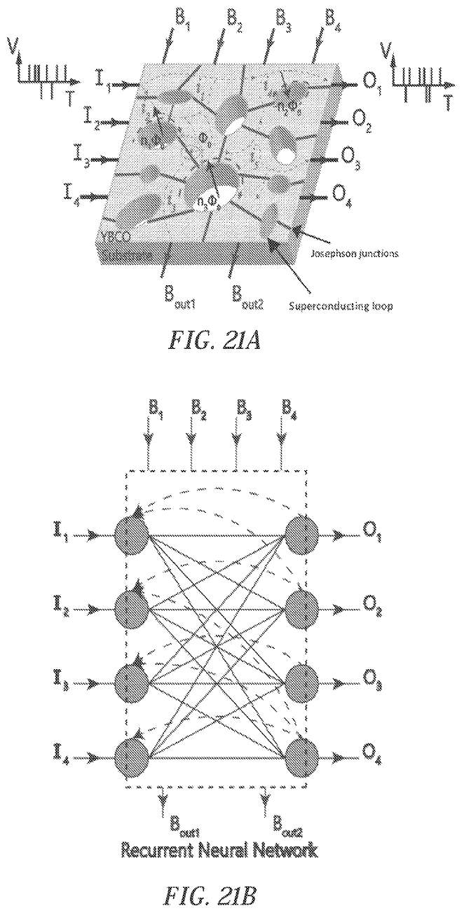

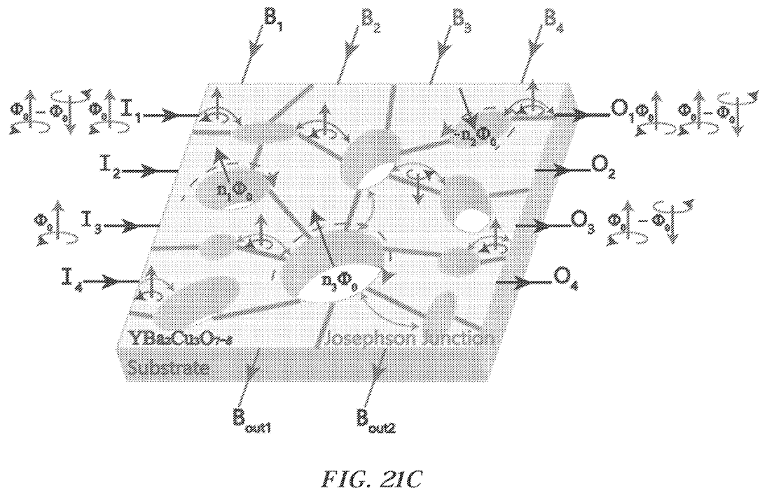

FIGS. 21A-21C show schematic of 4×4 superconducting disordered loop neural networks with He-ion beam defined Josephson junctions. FIG. 21A shows synapse network with 4 input channels (I₁, I₂, I₃, I₄), 4 output channels (O₁, O₂, O₃, O₄) and 4 control current/feedback channels (B₁, B₂, B₃, B₄) to represent all the individual synaptic connections of the recurrent neural network shown in FIG. 21B. The network comprises 10 superconducting loops connected through various Josephson junctions of different sizes. Incoming and outgoing spike trains are schematically represented for terminals I₁ and O₁. The input spike trains from all the terminals are converted into current pulses that take various time-dependent paths through Josephson junctions shown as i₁, i₂, etc. Some current pulses switch Josephson junctions above their critical currents and are stored as circulating currents in adjacent loops (i.e., flux perpendicular to the plane) representing the memory state of the synapse. The switching event and the generation/transfer of flux quanta are schematically shown using the dotted circle, and the flux stored in various loops is represented as n₁Φ₀, n₂Φ₀, etc. FIG. 21B shows schematic of an equivalent recurrent neural network with 4 input (I₁, I₂, I₃ and I₄) and 4 output channels (O₁, O₂, O₃ and O₄) and 4 external control current/feedback channels for external memory configuration. FIG. 21C shows flux quanta propagation through the synapse network shown in FIG. 21A. Flux can get trapped in loops and can propagate along different paths through the junctions to various output terminals. Variations in memory states result in differences in populations of flux quanta at each of the outputs.

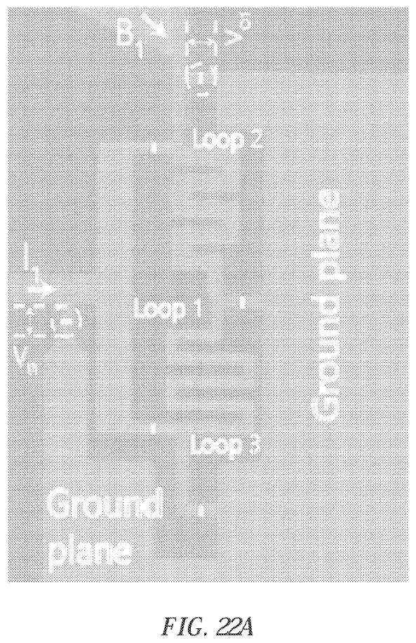

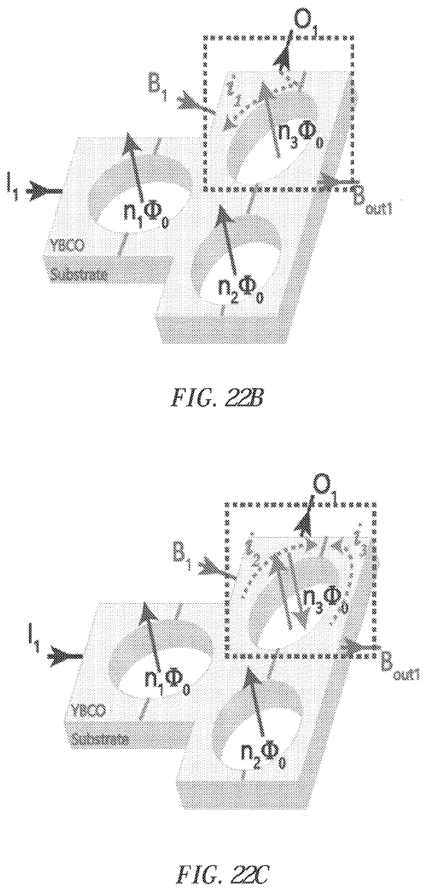

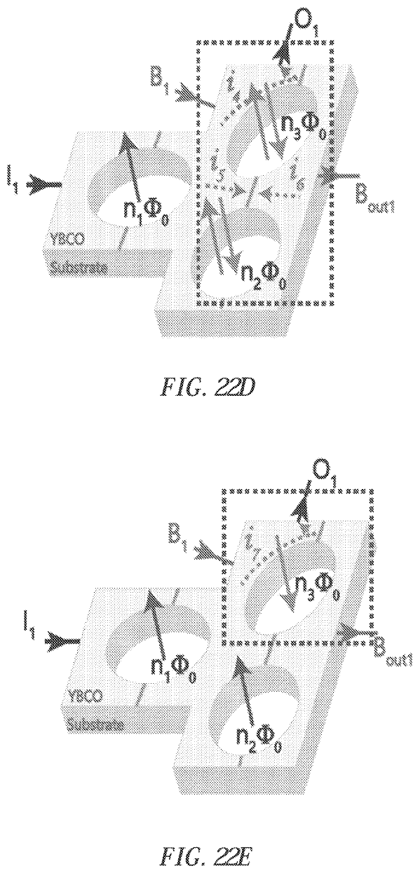

FIGS. 22A-22E show experimental 3-loop 1×1 superconducting disordered neural network. FIG. 22A shows optical microscope image of a YBCO-based 3-loop network with focused He-ion Josephson junctions used in the experiment to study the synaptic properties between 1 input-output terminal pair shown as I₁ and O₁. A control current parameter with current flowing between B₁ and ground can be used to change the memory configurations. Experiments involve excitation of the device with currents I₁ and B₁. The input and the control current are also varied in time relative to each other. FIG. 22B shows schematic of a 3-loop network showing currents and flux configurations in memory state S₁. Outgoing flux corresponds to anti-clockwise circulating currents in loop 2. FIG. 22C shows 3-loop network schematic showing memory state S₂ with an outgoing flow rate of zero. Currents and flux configuration corresponds to superconducting state of junction at O₁ with the current difference i₂-i₃ below its critical current. FIG. 22D shows 3-loop network schematic showing memory state S4 with increased outgoing flux flow. One of the junctions in loop 3 is in superconducting state (i.e., i₅-i₆ below its critical current) resulting in additional current diverted to the output. FIG. 22E shows 3-loop network schematic showing memory state S₅ with outgoing flux corresponding to clock-wise circulating current in loop 2.

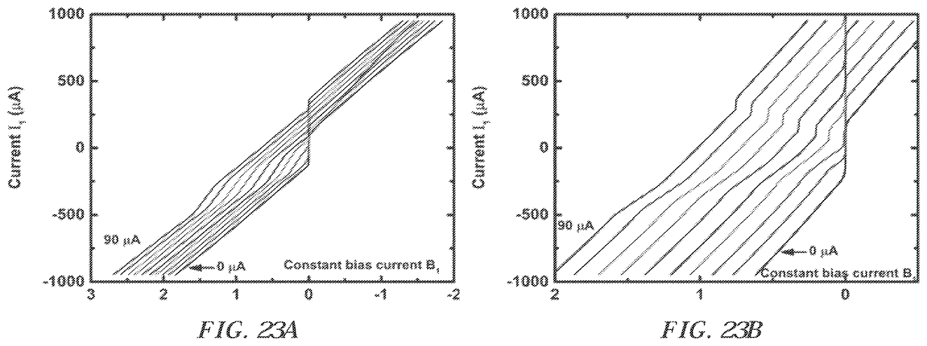

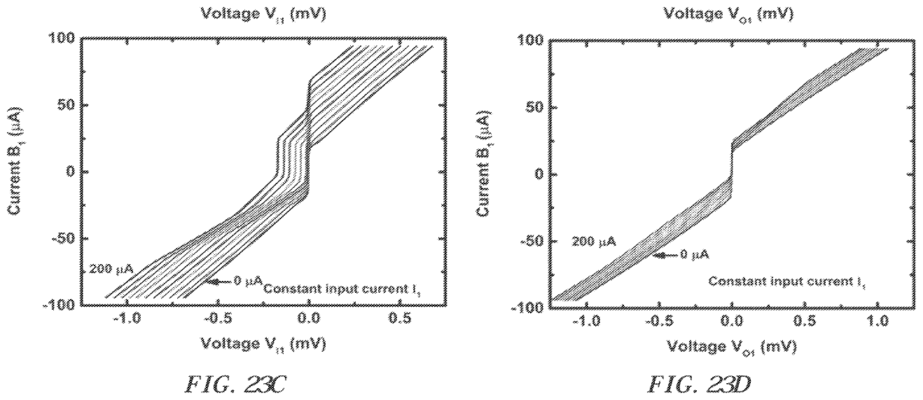

FIGS. 23A-23D show electrical characteristics-static operation. Current-Voltage characteristics of the 3-loop network shown in FIGS. 22A-22E corresponding to the experimental results of static operation. FIG. 23A shows current at input I₁ continuously varied between −1 mA and 1 mA is plotted against the measured input voltage I₁ while a constant control current is applied at B₁. 10 different measurements corresponding to currents at B₁ valued from 0 μA to 90 μA with an increment of 10 μA are plotted. FIG. 23B shows current at input I₁ continuously varied between −1 mA and 1 mA is plotted against the measured output voltage I₁ on at different constant control currents B₁ ranging from 0 μA to 90 μA with an increment of 10 μA. FIG. 23C shows current at B1 continuously varied between −90 μA and 90 μA is plotted against the measured input voltage V_{I1} while a constant input current is applied at I₁ (constant values ranging between 0 μA and 200 μA with an increment of 20 μA). FIG. 23D shows current at B₁ continuously varied between −90 μA and 90 μA is plotted against the measured input voltage V_{O1} on while a constant input current is applied at I₁ (constant values ranging between 0 μA and 200 μA with an increment of 20 μA).

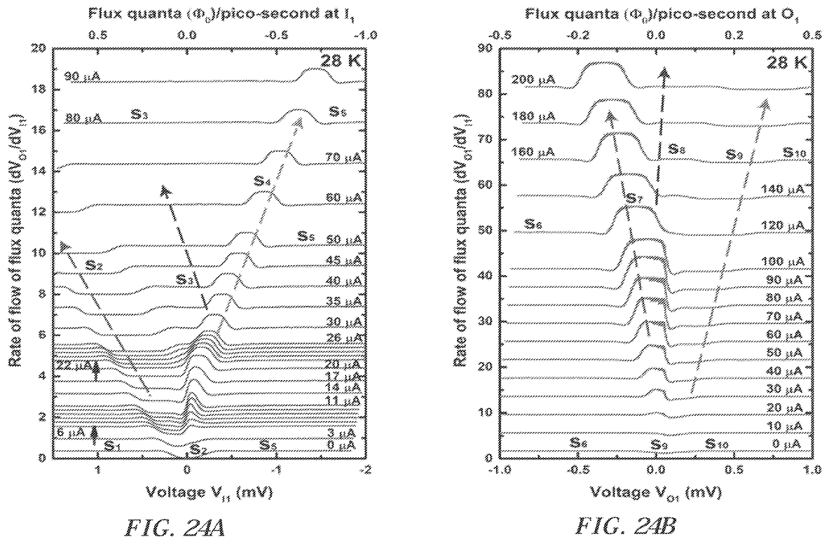

FIGS. 24A and 24B show evolution of memory states observed as different rates of flow of flux. Experimental observation of stable memory states in superconducting synapse networks in the form of rate of flow of flux between input-output terminals defined in a state-space of voltages (or frequencies of spiking signals into the network) and control currents. FIG.
dV_{O1}/dV_{I1}) through the 3-loop disordered array synapse network (FIG. 22A) measured at 28K while varying the input voltage I_{I1} (or corresponding current I₁) at different constant current biases B₁. The curves are offset in y-axis, with an offset value proportional to control current B₁ (i.e., an offset 0.2 per μA of B₁). Stable memory states are observed as constant rates of flow of flux labeled from S₁ to S₅. 3 stable states exist at B₁ of 0 μA with two new states emerging as B₁ is increased. FIG. 24B shows rate of flow of flux quanta (DV_{O1}/dV_{I1}) through the 3-loop synapse network (FIG. 22A) measured while continuously varying the input voltage V_{O1} (or corresponding current B₁) at different constant current inputs I₁. 3 different stable memory states are revealed initially, with 2 additional emergent states as I₁ is increased. The curves are offset in y-axis, with an offset value proportional to control current B₁ (i.e., an offset 1 per 2 μA of I₁). The voltages at which these states occur, and the width of the states can be configured using I₁.

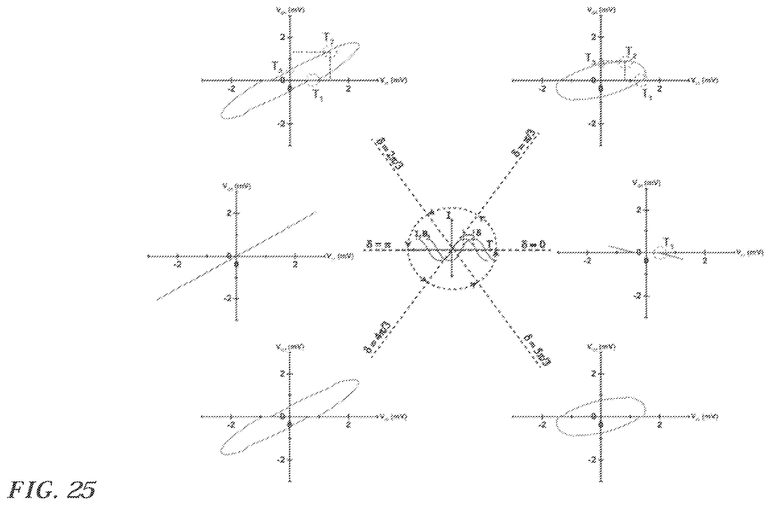

FIG. 25 shows dynamic transitions between memory states dependent on relative phase difference of input signals. Dynamic memory states and the corresponding state transitions experimentally observed in the state space of V_{I1} and V_{O1} as the phase difference δ is varied from 0 to 2π between sinusoidal current inputs I₁ and B₁, both of frequency 1 Hz and amplitudes 1 mA and 100 μA respectively. The movement of states and the state transitions around the space as δ is varied are labeled T₁, T₂ and T₃.

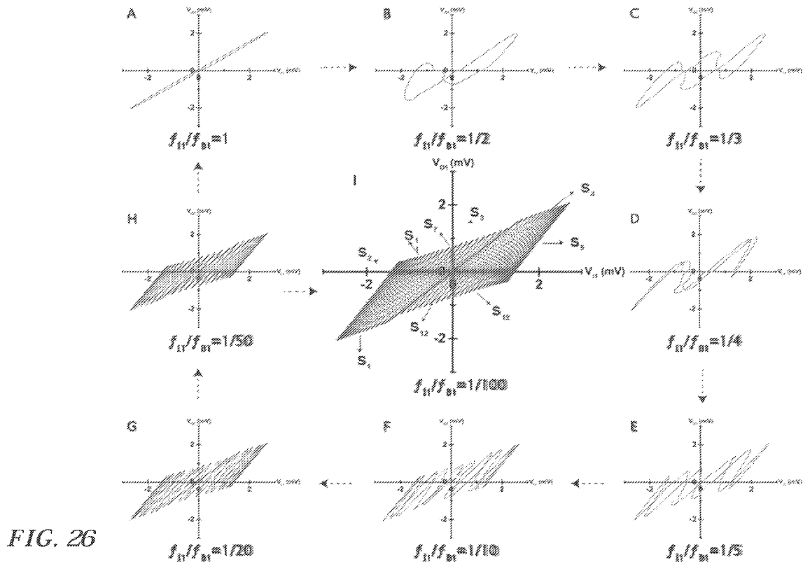

FIG. 26 shows electrical scan of state-space of operation of 3-loop 1×1 superconducting neural network. Dynamic memory states and the corresponding state transitions experimentally observed in the state space of V_{I1} and V_{O1} as the frequency of sinusoidal control current B₁ is varied from 1 Hz to 100 Hz with the input current at 1 Hz. The amplitudes of I₁ and B₁ are 1 mA and 100 μA respectively.

$$( A ) \frac{{f}_{I 1}}{{f}_{B 1}} = 1. \\ ( B ) \frac{{f}_{I 1}}{{f}_{B 1}} = 1 / 2. \\ ( C ) \frac{{f}_{I 1}}{{f}_{B 1}} = 1 / 3. \\ ( D ) \frac{{f}_{I 1}}{{f}_{B 1}} = 1 / 4. \\ ( E ) \frac{{f}_{I 1}}{{f}_{B 1}} = 1 / 5. \\ ( F ) \frac{{f}_{I 1}}{{f}_{B 1}} = 1 / 10. \\ ( G ) \frac{{f}_{I 1}}{{f}_{B 1}} = 1 / 20. \\ ( H ) \frac{{f}_{I 1}}{{f}_{B 1}} = 1 / 50. \\ ( I ) \frac{{f}_{I 1}}{{f}_{B 1}} = 1 / 100.$$

Different memory states, labeled from S₁ to S₁₃ and transitions between them can be observed that overlap with the states observed in the FIGS. 24A and 24B.

Realizing a physical system that can mimic information processing in biological brains (known as a neuromorphic computer) is a primary objective of next generation artificial intelligence (AI) systems and motivation for this work. There is still lack of full understanding of how memory and computation occur in brains that lead to higher-level properties such as cognition. Behavior of individual network elements, however, such as neurons, synapses, etc. are sufficiently well understood and implemented in different hardware systems. In neurons, packets of information flow in the form of action potentials as the accumulated signals (charge) from various other neurons surpasses their thresholds. This flow between neurons is regulated by the synapses in-between them. By varying their connection strengths or weights memory storage can be represented, and can either be potentiated or depressed in response to the information flow. This potential energy profile inspires the exploration of materials and devices that exhibit tunable electrical conductance behavior for use as synapses in neuromorphic computing.

At the network level, neuromorphic computation has been broadly understood as an emergent phenomenon arising from the collective behavior of these network elements through non-linear interactions, similar to other complex systems. In case of convolutional neural networks, processing is understood and practically implemented in the form of clustering and classification of digital information through a learning process, as the system converges to an energy minimum over a complex energy landscape. Physical implementation of analog information processing in neural networks is similarly explored in systems that exhibit complex energy landscape with non-linear spatial and temporal dynamics between network elements. Examples of such systems that result in emergent phenomena include disordered systems such as spin glasses, coupled oscillator networks, and also experimentally explored in nanowire networks, etc.

Complex systems with induced disorder in the network topology are also widely noted to be efficient for information processing and often observed in biological brain networks. The disclosed technology can be implemented in some embodiments to provide a spiking recurrent neural network architecture based on a disordered array of superconducting loops where disorder is introduced in the form of circuit topology between network connections (i.e., synaptic network between neurons).

Fluxon generation and propagation through Josephson junctions, observed as spiking voltages are well-understood and superconducting loop based circuits encompassing individual fluxons are subsequently developed for use in rapid single-flux quantum digital circuits for energy-efficient and high-speed digital computing. Collection of a large number of such quantized flux can similarly be stored in superconducting loops in the form of circulating super-currents with Josephson junctions interrupting that loop acting as gateways for their entrance or exit. Such spiking signals can therefore represent both spatial and temporal information similar to that of biological brains. Therefore, a multi-terminal network of disordered loops with junctions such as that shown in FIG. 21A can replicate the individual synaptic connections of a recurrent neural network such as that shown in FIG. 21B, where complex non-linear interactions between the incoming and the stored fluxons result in variation of the average flow of spiking signals between any pair of input-output terminals as shown in FIG. 21C. The rate of flow of fluxons between any two terminals, defined quantitatively and demonstrated experimentally in this patent document, may be characterized as synaptic weight between them.

Specifically, the incoming flux at I₁ say enters in the form of current pulses that propagate through the network in different time-dependent paths to different output terminals such as O₁. When some of these currents surpass the superconducting critical current of a junction in its path, I_{c}, fluxons enter the corresponding loop and are stored in the form of circulating current (i.e., memory) around that loop. These processes are schematically shown in a network of 10 loops with four input and four output terminals (Iₙ, and Oₙ) in FIG. 21A. The flow of flux can also be separately controlled using the current terminals (Bₙ), which can also be a function of outgoing signals through a feedback loop (from perhaps Oₙ).

The disclosed technology can be implemented in some embodiments to provide a collective synapse network that includes a network of interconnected YBa₂Cu₃O_{7-δ} (YBCO) superconducting loops and Josephson junctions, where disorder is introduced into the network architecture in the form of geometry and physical properties of loops and Josephson junctions (i.e., the loop inductances and junction critical currents). The YBCO-based experimental 3-loop network with 1-input (I₁), 1-output (O₁) and 1-feedback (B₁) terminal is shown in FIGS. 22A-22E. Such networks can be combined with compatible elements such as superconducting spiking neurons, etc., to form fully connected recurrent neural networks that can be configured to perform both supervised and unsupervised learning.
LᵢI_{c}/Φ₀ where, Lᵢ is the inductance of the superconducting path around loop i and I_{c} is the critical current of the smallest Josephson junction in that loop. Therefore, the total number of distinct static memory configurations available for an array with number of loops equal to i is given by (2n₁+1)·(2n₂+1) . . . (2nᵢ+1) accounting for states with no current, clockwise or anti-clockwise circulating currents in the loops. This number grows exponentially as the number of loops increase. The memory states can be characterized as meta-stable states of circulating currents corresponding to local energy minima for flux propagation through the network. Due to the presence of nonuniform loop inductances and junction critical currents, each of the pathways for the flow of flux between any two terminals are subjected to a distinct energy landscape that is dependent on the memory state, as well as the input conditions. As the flux gets trapped and is propagating between loops, the memory state and its corresponding energy configuration defines the propagation probability of an input fluxon (and therefore the corresponding fluxon flow rate) through any of the available paths (allowing measurement of the memory state and its time-evolution) as shown schematically in FIG. 21C. Specifically, the potential energy stored in a loop k due to the flux storage and current paths through it can be calculated as shown in equation (4) below. Similarly, the energy landscape of any of the current paths from an input node (say I₁) to an output node (say O₄) can be calculated as a function of junction and inductance parameters along the pathway using equation (4):

$${U}_{k} = - {\sum }_{m = 1}^{M} \frac{{I}_{{C}_{m}} {Φ}_{0}}{2 π} cos ( {φ}_{m} + {α}_{m} ) + {\sum }_{n = 1}^{N} \frac{{( {Φ}_{0} \cdot ( {φ}_{m} + {β}_{n} + 2 π {n}_{i} ) )}^{2}}{4 π {L}_{n}} \qquad Eq . ( 4 )$$

Here, the loop k is assumed to contain M different Josephson junctions with critical currents I_{C}_{ₘ} and N different inductances, representing the N branches of the loop between the junctions. Po is the magnetic flux quantum of value 2.06783383×10⁻¹⁵ Wb. Following the Josephson equations for overdamped junctions, φₘ is the phase difference across junction m and is dependent on the current through it, while αₘ is due to the flux in the inductively coupled adjacent loop branch. nᵢ is the number of flux quanta stored in the loop i and βₙ is a function of the control or input currents. Therefore, the potential energy of the loop depends on the flux stored along with the input and control currents. In a dynamic system with continuous spiking excitation at the inputs, the incoming flux encounters multiple paths to all the output terminals, with different time-dependent energy landscapes resulting in a different rate of flow of flux for each path corresponding to the memory/flux configurations. The different paths represent synaptic weights. While it is considerably complex to experimentally determine the energy distribution in each of these paths as a function of time, the effect of different energy landscapes on fluxon flow rates can be experimentally measured as shown below. These flux outputs can be connected to superconducting leaky integrate-and-fire neurons and feedback loops, where the flow rate of flux above a frequency threshold is translated into the amplitude and frequency of spiking action potentials.

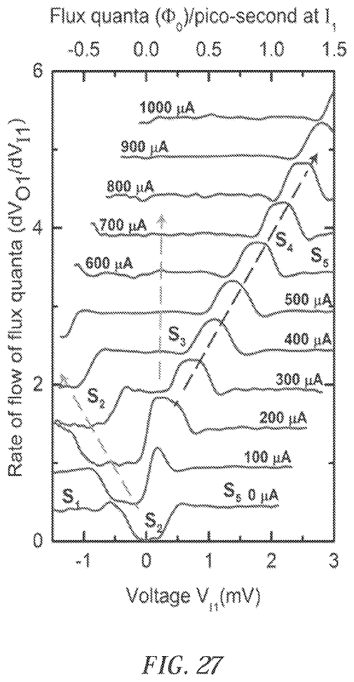

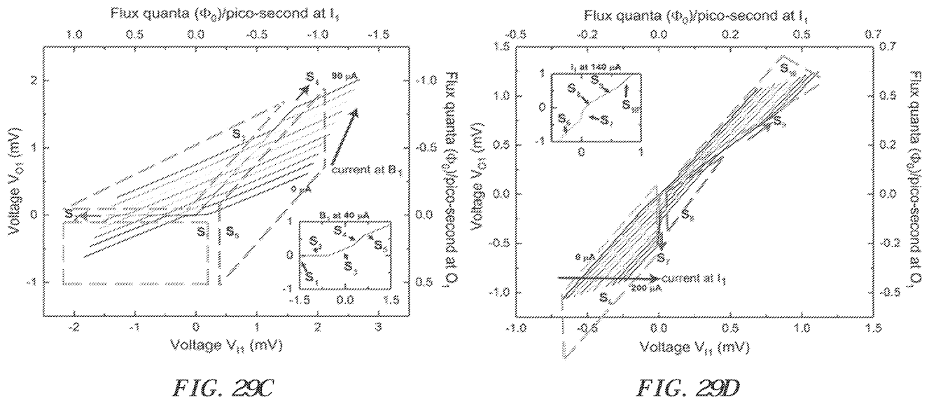

A simplified network of 3 disordered loops with a total of 5 dissimilar Josephson junctions shown in FIG. 22A was designed to experimentally realize the synaptic properties discussed above. The network is fabricated using high-temperature superconductor YBCO with Josephson junction barriers defined using focused helium ion beam direct writing. Loop 1 is inductively coupled to loops 2 and 3, which are connected to each other through a Josephson junction. An additional junction shunted to ground is connected to loop 1 at its input terminal. The input current applied predominantly passes through this junction generating a spiking input to the 3 loops equivalent to the average rate of incoming flux quanta V_{I1}/Φ₀ proportional to current I₁. A control current signal B₁, that can also be programmed to represent a feedback signal, is applied to loop 3 near the output junction across which the average frequency of outgoing flux quanta V_{O1}/Φ₀ is measured, such that feedback current can induce back-propagating flux. The 3-loop design encompasses at least one instance of all possible flux-current interactions occurring in a larger nonuniform network. Therefore, it can also be considered as a subset of a larger network where the applied currents I₁ and B₁ correspond to some instances of flux and continuous current entering from neighboring loops. I₁ and B₁ in FIGS. 22A-22E were systematically varied to drive the network into different stable memory states, and therefore map the memory state-space represented by the resulting input and output voltages V_{I1} and V_{O1}, equivalent to their respective incoming and outgoing frequencies of fluxons into the network. Each of the loops was designed to accommodate a total circulating current equivalent to a few tens of flux quanta before the critical currents are reached and the flux quanta begin to exit the loops through the junctions, thus allowing a large number of distinct memory configurations. Non-uniformity was built into the network in the form of dissimilarities in loop geometries (i.e., inductances) and junction critical currents. The network corresponding to results in FIGS. 23A-23D to 26 and supplementary FIGS. 29 to 32 is operated at 28 Kelvin. However, another 3 loop network designed with different junction critical currents but similar loop inductances and operated at 4.2 Kelvin produced qualitatively similar results with similarly evolving memory states (see supplementary FIG. 27) indicating that the accuracy of the design parameters and the measurement temperature (below its superconducting critical temperature) are not crucial to achieve a particular operation of the neural network. Furthermore, this implies that our approach is robust to effects of disorder from uncontrollable fabrication processes and material variations.

The flux flow rate through the network between any pair of input-output terminals in the network is defined as change in the average number of fluxons leaving the network through the output V_{O1} on with respect to change in the average number of fluxons entering the network at the input terminal I_{I1}. Therefore, in the 3-loop network, the flow rate of fluxons between the input and output terminals, equivalent to its synaptic weight, is given by dV_{O1}/dV_{I1}.

Static operation: Initially, current I₁ is sinusoidally varied between −1 mA and 1 mA while the current B₁ is fixed. The measurement is repeated for different values of B₁ ranging from 0 μA to 90 μA. In some implementations, the applied currents are significantly larger than the critical currents of the junctions, or the circulating currents corresponding to different memory states. This is by design, such that the flux propagation through the network occurs at very high frequencies (up to THz) and the resulting memory states are stable and considerably distinct in their respective energy landscapes. Only such memory states are observed as causing substantial differences in rates of flux flow and the patterns in these emergent memory states are clearly seen, as input conditions are varied. However, at much lower currents, the differences in flow rates between each different memory state may be observed in the output spiking signals. In some implementations, the frequencies of sinusoidal current inputs are in the range of a few Hz to 1 kHz. This is 5 orders of magnitude slower than the corresponding spiking frequencies, and therefore allows enough time for the system to relax to a local energy minimum (representing the memory state), behaving as a quasi-static system on the timescale of applied currents. The input current-input voltage characteristics of the 3-loop network are shown in FIG. 23A-23D and the input current-output voltage characteristics are shown in FIG. 23B. The rates of flux flow, i.e., dV_{O1}/dV_{I1}, obtained from our measurements are plotted against the input voltage V_{I1} for different constant control currents B₁ in FIG. 24A. The corresponding voltages V_{O1} on against V_{I1} representing the rate of incoming and the outgoing fluxons to the network from which the flux flow rates (FIG. 24A) are obtained, for some of the constant currents at B₁ are shown in supplementary FIG. 29C.

Our results clearly show that multiple stable memory states exist (different values of dV_{O1}/dV_{I1}), labeled as S₁, S₂, . . . S₆ in FIG. 24A, during which the rate of flow of fluxons between the input-output terminals remains constant. The average fluxon flow rates through the network are different for different input voltage ranges as shown in FIGS. 24A and 24B, and also observed as linear current-voltage regions in FIGS. 23A and 23B. The changes in slope of these linear regions correspond to the transitions in memory states, indicating that the total current through different paths changes with memory (flux) configurations. Alternatively, this can be described as a different rate of flow of flux through each of the paths for different memory states. These results also show different mechanisms for switching between memory states as described schematically in FIGS. 22B-22E. For example, a superconducting to voltage state transition occurs at zero voltage in the plots shown in FIGS. 23A-23D. These transitions correspond to different current configurations (i.e., at I₁ and B₁) at which the current through junctions at V_{I1} or V_{O1} abruptly surpasses their respective critical currents. However, such abrupt transitions also occur at finite voltages as observed in FIGS. 23B and 23C, indicating that one of the other junctions in the network transitioned between superconducting and voltage states. These transitions correspond to differences between memory states described as S₁, S₂ and S₅ in FIGS. 22B-22E. The transitions can also occur over a range of voltages (for example, between −2 m V and 0 m V for currents between −500 μA and 0 μA in FIG. 23A), where the changes in current paths from one configuration to the other is gradual, therefore acting as another stable memory state shown as S₄ in FIGS. 24A and 24B.

These stable states correspond to sets of trapped flux configurations during which the changes in current through the junction at O₁ is negligible. This is because the applied currents at I₁ and B₁ are considerably larger than the circulating currents due to flux in loops. However, differences in the flow rates are significant between different stable states. Distinctions in flow rates between each fluxon configuration (memory state) are expected to be observed when the currents through any of the paths are of magnitude similar to the critical currents of junctions in that path. When B₁ is 0 μA, three different memory states, labeled S₁, S₂ and S₅ are observed, with transitions occurring at −0.2 m V and 0.2 mV. When V_{I1} is between −0.2 mV and 0.2 mV, dV_{O1}/dV_{I1} is 0, and the output junction is in superconducting state corresponding to zero output flow rate in FIG. 24A. Input voltage V_{I1} versus voltage V_{O1} (FIG. 24A) and input current I₁ versus voltage V_{O1} on FIG. 23B also show that the junction is in the zero voltage state in S₂. At above 0.2 mV and below −0.2 m V, the V_{O1} varies linearly with V_{I1} to yield respective constant average fluxon flow rates.

Increasing B₁ (FIG. 24A) results in new memory states gradually emerging from within the existing states. Two such instances are observed with state S₄ emerging between B₁ of 6 μA and 11 μA (schematically shown in FIG. 22D) and with state S₃ emerging between 22 μA and 26 μA. The number of observable memory states in the form of distinct flow rates increase from 3 at B₁ of 0 μA to 5 at B₁ of 30 μA. These different states correspond to one of the junctions switching between the superconducting and voltage states either abruptly (i.e., at fixed values of I₁ or B₁), or gradually over a range of values of I₁ due to continuous transfer of flux quanta between loops. For example, a memory state S4 with a larger fluxon flow rate fully emerges at B₁ of 26 μA between V_{I1} of 0 m V and 0.4 mV. Such distinct states are a result of one of the junctions in loop 2 transitioning from the superconducting to voltage state resulting in a considerable increase in current through the output junction in that state as shown in FIG. 22D. The control current B₁ can also be used as a controllable parameter to change the input frequency (i.e., V_{I1}/Φ₀) and the bandwidth over which different memory states are observed, shown in FIG. 24A. When B₁ is increased, the memory states corresponding to a flow rate of 0 gradually shift away from V_{I1} of 0 m V to negative voltages until they are out of the measurement scale above B₁ of 70 μA. The voltage range (bandwidth) of the memory state increased from 0.4 m V (193 GHZ) at B₁ of 0 μA to 0.8 mV (387 GHZ) at B₁ of 26 μA, and remains constant at larger currents. Similar patterns are observed in all the other memory states, where the bandwidth and voltage ranges for the memory states and their emergence can be continuously tuned.

An inverted test is conducted to induce back-propagating flux (i.e., from output O₁ to input I₁) by continuously varying the control current B₁ between −100 μA and 100 μA at different lower constant input currents I₁. The resulting flux flow rates are plotted against the output voltage V_{O1} for I₁ between 0 μA and 200 μA in FIG. 24D. A completely different set of memory states labeled from S₆ to S₁₀ are observed, characterized by different flow rates, voltage ranges and bandwidths. These are observed as linear current-voltage regions across input and output junctions in FIGS. 23C and 23D. Patterns similar to that of FIG. 24A can be observed, with 3 distinct states at I₁ of 0 μA evolving in to 5 states at I₁ of 160 μA and larger. However, the corresponding rates of flow of flux are significantly larger than ‘1’ indicating that fluxon flow rate is in the opposite direction (from output O1 to input I1).

Dynamic operation: The results discussed above prove that stable memory/flux configurations exist in synapse networks that can be classified into different categories corresponding to their rates of flow of flux quanta between the input-output nodes in the state-space defined by input voltage V_{I1} and output voltage V_{O1}. Additionally, these categories can be continuously configured using the control currents. These results represent static operation where the network is subjected to constant frequency spiking input I₁(B₁) and a constant control current B₁(I₁) that holds the network in a stable memory state. A change in memory state corresponds to a significant change in the flux flow rate dV_{O1}/dV_{I1} for the same input frequency V_{I1}/Φ₀ as shown in FIGS. 24A and 24B. A leaky integrate-and-fire neuron can be configured to generate action potentials over a specific range of frequencies defined by ±f_{T}, where f_{T} is the frequency threshold of the neuron, acting as a band-pass filter for spiking signals. Here, the negative frequency represents flux flow in the opposite direction. Therefore, the relative population densities of outgoing flux-quanta associated with each memory state defined in a configurable frequency window±f_{T} can be measured.

However, during the neural network operation of the disordered array of superconducting loops, the input spike frequency dynamically changes with respect to the control current (i.e., both the signals are actively changing with respect to each other). While the spiking input signal maps the spatial and temporal information on to the memory state-space, the feedback/control current signal re-configures the memory state-space according to the outgoing spike signals during the learning process. In this dynamic operation, the fluxon flow rate (equivalent to its synaptic weight) depends on the relative time difference Δₜ between the pre and post-synaptic spiking analogous to that of spike-timing dependent plasticity. Experimentally, the dynamic behavior is experimentally observed in frequency state-space (of input and output spiking signals) by dynamically varying both the currents I₁ and B₁ relative to each other. The memory states and their history can be mapped on to the state-space of incoming and outgoing spike frequencies, and the effect of Δₜ on the flux flow rate can be observed by varying the phase δ and frequency f of one of these currents with respect to the other where

$$Δ t = \frac{δ}{2 π f} .$$

The memory states observed in FIGS. 24A and 24B and the transitions between them are continuously configured between a wide range of voltages and across different bandwidths as the relative phase δ or frequency f of one current signal is varied with respect to the other. The results are shown in FIGS. 25 and 26 as Lissajous curves in the spiking signal frequency state-space defined by V_{I1} and V_{O1}, as the space is scanned by continuously varying the currents I₁ and O₁.

Initially, a sinusoidal signal of amplitude 1 mA and frequency 1 Hz is applied at I₁, and a similar signal of amplitude 100 μA at the same frequency is applied at B₁, similar to the currents applied in static operation in FIGS. 24A and 24B. FIG. 25 shows V_{O1} on against V_{I1} as the phase of B₁ is varied relative to I₁. Transitions between memory states are labeled in the figure as T₁, 7₂ and 7₃ with T₁ corresponding to transitions S₁-S₂-S₃, T₂ corresponding to transitions S₃-S₄-S₅ and T₃ corresponding to S₃-S₇-S₁₁. As phase difference o is varied between 0 and 2π, state transitions move around the state-space of V_{I1} and V_{O1}, as the span of frequency windows, i.e., the bandwidths across which the transitions are observed, changes in size. For example, T₁ is observed between V_{I1} of ±0.5 m V at δ=0, but is moved to V_{I1} between 1.3 m V and 1.5 m V at δ=π/3, and to V_{I1} between 0.6 m V and 1 m V at δ=2π/3 as it completely disappears at δ=π. Similar dynamics are observed for T₂ and T₃.

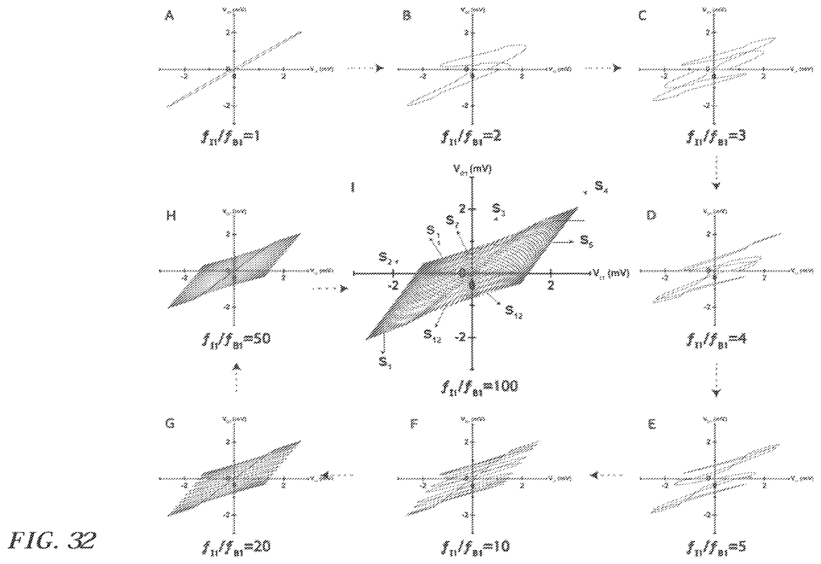

To further explore the memory states and their transitions in the space defined by V_{I1} and V_{O1}, frequency of one of the currents, i.e., B₁ is varied with respect to the other, i.e., I₁ and the results are shown in FIG. 26. By systematically increasing the frequency of one of the current signals with respect to another, the entire memory state-space where the neural network can operate (for the given bandwidth) has been mapped. Here, a current amplitude of 1 mA and frequency 1 Hz is applied at I₁ while a current amplitude of 100 μA is applied at B₁ with its frequency varying from 1 Hz to 100 Hz. Different memory state classifications separated by their transitions evolve as the frequency ratio is increased. Each of these memory states correspond to a different fluxon flow rate between I₁ and O₁ (FIGS. 22A-22E). An almost continuous state-space is divided into 9 different categories that can be distinguished by various transitions caused by different junctions in the network switching into and out of superconducting state. The state-space is also scanned by varying the frequency of I₁ from 1 Hz to 100 Hz with B₁ constant at 1 Hz to reveal the 9 different memory states as shown in supplementary FIG. 32. In some implementations, the transitions are also labeled as memory states here as they present a region in the state-space where they are stable.

During the neural network operation, the spiking signals and the currents are dynamically varying in response to the input information. As the corresponding transient current flows through different paths of the disordered network into multiple outputs as shown in FIGS. 21A-21C, the information is classified or clustered into different categories that can be observed in the form of populations of flux quanta across the stable memory states observed in the frequency state-space of input and output spiking signals. Different neurons can be designed to access these flux quanta populations in specific frequency bands corresponding to either individual or multiple overlapped memory states. The neurons and synapse networks can be connected in the form of recurrent neural networks enabling hierarchical architecture similar to biological brains. Such superconducting disordered loop array architecture based network also provides a platform to explore rich spatial and temporal dynamics associated with analog neural networks.

The disclosed technology can be implemented in some embodiments to provide a network of YBCO-based superconducting loops with Josephson junctions in the context of a dynamic memory/synapse network for use in neuromorphic computing. The role of disorder in neuromorphic network architectures can be understood through complex superconducting networks, that can also be expanded to other material systems. However, superconducting networks correspond to superior operating speeds with maximum spike frequencies up to a few THz with an ultra-low energy dissipation in the order of ≈2×10⁻¹⁸ Joules per spike, with power dissipation dependent on the operating frequencies. Additionally, the proposed YBCO-based superconducting loops enable high scalability with loop widths as small as 10 nm, higher operation temperatures, and exponentially scaling memory capacity with number of loops.

The experimental 3-loop disordered array, shown in FIG. 21, is fabricated from the high-temperature superconductor YBCO film. Josephson junction barriers are defined using a focused ion beam from a He-ion microscope. In this particular device, each loop is designed to have a large inductance to accommodate several flux quanta ranging between 20 to 60 Φ₀ per loop. The critical currents of different junctions are varied between 100 μA and 150 μA using the dose of the-ion-irradiation while fabricating the tunnel barrier with junction width kept constant.

Samples were fabricated from wafers of 35 nm thick YBCO capped with 200 nm of gold deposited in-situ for electrical contact. The YBCO layer was grown via thermal reactive co-evaporation on a CeO₂ buffered sapphire substrate. Samples were diced from this wafer into 5×5 mm² squares.

A photolithography and ion milling process was utilized to define the bulk electrodes that would make up the loop array, ground plane and terminals. Samples were spin-coated for 45 sec at 5000 rpm with photoresist. The photoresist is exposed with a 405 nm GaN solid state laser defining the layout pattern. The photoresist was developed and mounted into a broad beam argon ion mill. This ion milling isolated the traces and loops of the layout design by milling away material. A second lithographic step was performed to open apertures in the gold capping layer such that the He-ion irradiation could be incident directly on the YBCO layer. A 200×200 μm² square region that contained all the locations for the Josephson junctions was exposed to Ki⁺ etch to chemically remove the gold layer while maintaining the YBCO thin film. An optical image of the output of these fabrication steps is presented in FIG. 22A.

The sample was then mounted in a gas field ion source. The focused ion beam produced can be focused to a beam spot size on the scale of 1 nm, and controlled with sub-nanometer resolution. The beam parameters utilized in the fabrication of the Josephson junctions was a 0.5 pA He ion beam accelerated at 32.5 kV. This beam was rastered in a line across the lithographically defined electrodes introducing an average ion fluence of 4×10¹⁶ ions/nm to define the Josephson barriers. Ion fluence influences the nature of the barrier, practically effecting the critical current of the Josephson junctions. Actual ion fluence was varied up to 25% from the average causing variations in the Josephson junction critical currents intentionally to introduce the disorder (i.e., non-uniformity) in the loop array. Locations of the Josephson junction irradiated regions are indicated in FIG. 22A.

After fabrication, the sample was mounted in a J-Lead 44-pin chip carrier. Electrical contacts between the sample and the chip carrier were made via Al wire bonds. The chip carrier was then inserted into a socket at the tip of a cryogenic insert probe which was evacuated and back-filled with 500 m Torr of helium gas meant for temperature exchange. The insert was cooled inside a liquid helium storage dewar where the temperature may be controlled by adjusting the tip height in relation to the liquid helium surface. The temperature was held at 28 K temperature for all the experiment measurements reported, except for the results shown in FIG. 27, the measurements of which were performed at 4.2K.

FIG. 27 shows control experiment—evolution of memory states observed as different rates of flow of flux. Experimental observation of similar stable memory states in a different but topologically similar 3-loop network discussed above). Different ion-doses are used while defining Josephson junctions and the experiment is conducted at 4.2K to obtain different critical currents. The input current I₁ is continuously varied between −1 mA and 1 mA at different constant control currents B₁ in the range of 0 μA and 1000 μA with an increment of 100 μA.

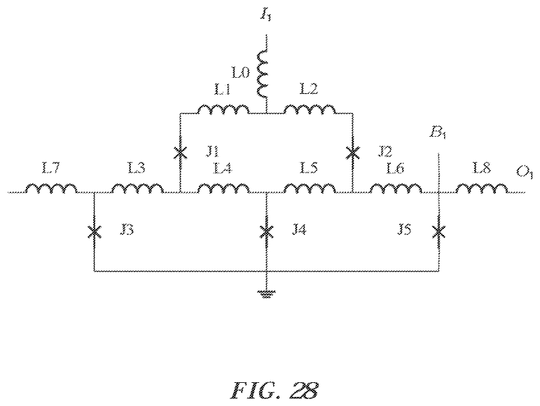

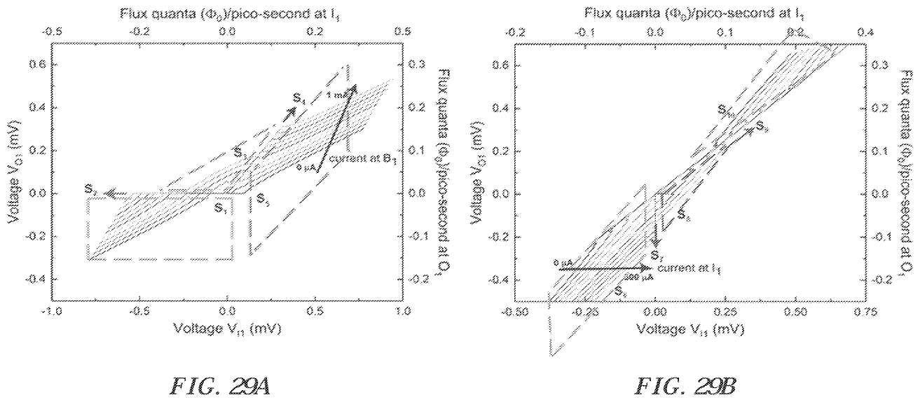

FIG. 28 shows equivalent circuit model of the experimental 3-loop network. Electrical lumped-element circuit model of the 3-loop network discussed above can be used in circuit simulations. The output voltage V_{O1} is measured across junction J5. The circuit is completely disordered with no two junctions or inductors identical to each other, but the exact circuit parameter values are arbitrarily chosen (similar to the experimental device design). Simulation parameters: Critical currents of junction J1:140 μA, J2:110 μA, J3:120 μA, J4:100 μA and J5:160 μA. Inductance: L0:4 pH, L1:8 pH, L2:7 pH, L3:10 pH, L4:40 pH, L5:85 pH, L6:12 pH, L7:4 pH and L8:4 pH.

FIGS. 29A-29D show comparison of experimental and simulation results. FIG. 29A shows simulation results of V_{O1} plotted against V_{I1} for different control currents B₁ corresponding to the circuit in FIG. 28. 10 curves for B₁ from 0 μA to 1 mA are shown with an interval of 100 μA. No offset is added to the curves. Different regions of stable memory states are labeled. These results are topologically similar to the measurement results shown in (C). FIG. 29B shows simulation results of V_{O1} versus V_{I1} for different input currents I₁ corresponding to the circuit in FIG. 28. 10 curves for I₁ from 0 μA to 500 μA are shown with an interval of 50 μA. No offset is added to the curves. Different regions of stable memory states are labeled. FIG. 29C shows experimental V_{O1} versus V_{I1} for different control currents B₁ corresponding to the plots in FIG. 24A. 10 curves for B₁ from 0 μA to 90 μA are shown with an interval of 10 μA. No offset is added to the curves. Different regions of stable memory states are labeled. Inset shows V_{O1} versus V_{I1} for B₁ of 40 μA to highlight all the memory states observed. FIG. 29D. Experimental V_{O1} versus V_{I1} for different input currents I₁ corresponding to the plots in FIG. 24B. 10 curves for I₁ from 0 μA to 200 μA are shown with an interval of 20 μA. No offset is added to the curves. Different regions of stable memory states are labeled. Inset shows V_{O1} versus V_{I1} for I₁ of 140 μA to highlight all the memory states observed.

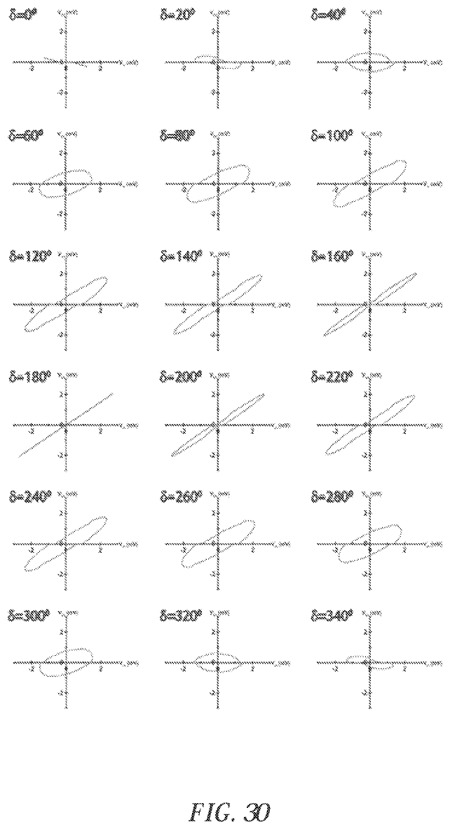

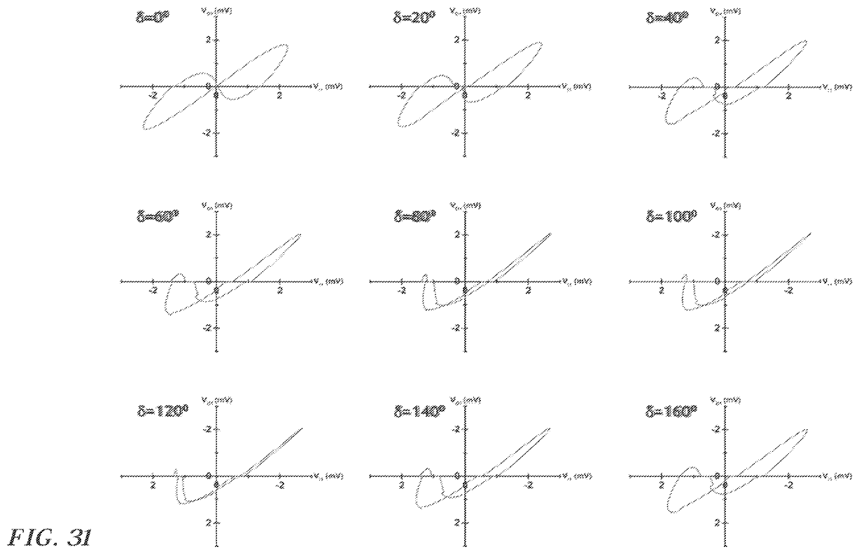

FIG. 30 shows dynamic transitions between memory states dependent on relative phase difference of input signals from 0 to 2π. Dynamic memory state s and the corresponding state transitions experimentally observed in the state space of V_{I1} and V_{O1} as the phase difference δ is varied from 0° to 360° with an interval of 20° between sinusoidal current inputs I₁ and B₁ both of frequency 1 Hz and amplitudes 1 mA and 100 μA respectively.

FIG. 31 shows complete phase diagram of the dynamic memory states and the corresponding state transitions. Experimentally observed in the state space of V_{I1} and V_{O1} as the phase difference δ is varied from 0° to 180° with an interval of 20° between sinusoidal current inputs I₁ and O₁ of frequencies 2 Hz and 1 Hz and amplitudes 1 mA and 100 μA respectively.

FIG. 32 shows electrical scan (inverted) of state-space of operation of 3-loop 1×1 superconducting neural network. Dynamic memory states and the corresponding state transitions experimentally observed in the state space of V_{I1} and V_{O1} as the frequency of sinusoidal input current I₁ is varied from 1 Hz to 100 Hz with the control current B₁ at 1 Hz. The amplitudes of I₁ and B₁ are 1 mA and 100 μA respectively.

$$( A ) \frac{{f}_{I 1}}{{f}_{B 1}} = 1. \\ ( B ) \frac{{f}_{I 1}}{{f}_{B 1}} = 2. \\ ( C ) \frac{{f}_{I 1}}{{f}_{B 1}} = 3. \\ ( D ) \frac{{f}_{I 1}}{{f}_{B 1}} = 4. \\ ( E ) \frac{{f}_{I 1}}{{f}_{B 1}} = 5. \\ ( F ) \frac{{f}_{I 1}}{{f}_{B 1}} = 10. \\ ( G ) \frac{{f}_{I 1}}{{f}_{B 1}} = 20. \\ ( H ) \frac{{f}_{I 1}}{{f}_{B 1}} = 50. \\ ( I ) \frac{{f}_{I 1}}{{f}_{B 1}} = 100.$$

Different memory states, labeled from S₁ to S₁3 and transitions between them can be observed that overlap with the states observed in the FIGS. 22B and 22C.

The stable flux flow rates observed in FIGS. 23 and 24 correspond to different currents along various paths (or different flux configurations in loops). Therefore, similar memory states can be observed in a topologically similar network irrespective of the actual device parameters. The experiment described in FIG. 22A is repeated on a different but topologically similar 3-loop network operated at 4.2K. The He-ion fluences used to define the Josephson junctions are different resulting in different critical currents. However, the results indicate topologically similar memory states as shown in FIG. 27. To further support this conclusion, an equivalent electrical circuit model of the 3-loop network is simulated using an arbitrary set of circuit parameters as shown in FIG. 28. The input current I₁ and control current B₁ are systematically varied to simulate the experiment presented in FIGS. 23 and 24 and the results are shown in FIGS. 29A and 29B. These results are qualitatively similar to the experimental results (shown in FIGS. 29C and 29D) indicating that the emergent memory states observed are due to various flux configurations, and are subject to the network topology.

The dynamic operation of the 3-loop network is explored by varying the phase and frequency of one of the currents I₁ (B₁) with respect to another B₁ (I₁) and the results are shown in FIGS. 25 and 26. The complete data set corresponding to the relative phase δ of B₁ varied with respect to I₁ with an interval of 200 is shown in FIG. 30 in the state-space of V_{I1} and V_{O1}. Similarly, the frequency of sinusoidal input current I₁ is doubled such that

$$\frac{{f}_{I 1}}{{f}_{B 1}} = 2.$$

The resulting dynamic memory states are shown in the state space of V_{I1} and V_{O1} as the relative phase difference δ is varied from 0° to 180° with an interval of 20° is shown in FIG. 31. FIG. 26 shows the dynamic memory states as the frequency of B₁ is varied from 1 Hz to 100 Hz (i.e., In is varied from 1 to 1/100) while the current I₁ is at 1 Hz. Similarly, the current I₁ is varied from 1 Hz to 100 Hz with frequency of B₁ at 1 Hz (i.e., f_{I1}/f_{B1} is varied from 1 to 100) and the results are shown in FIG. 32.

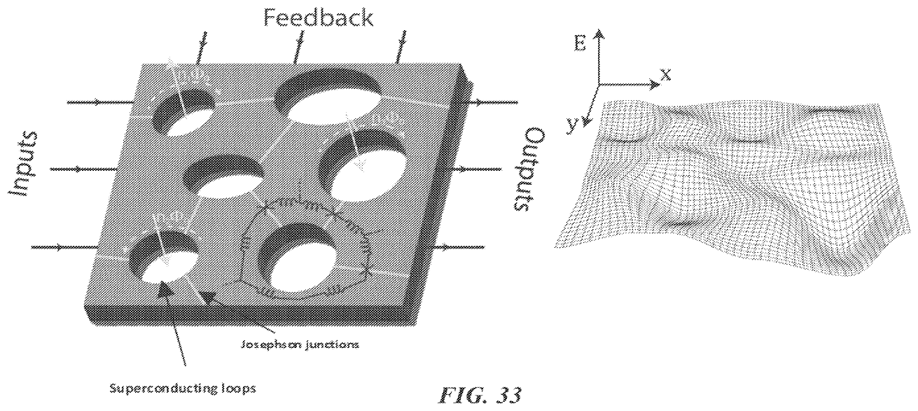

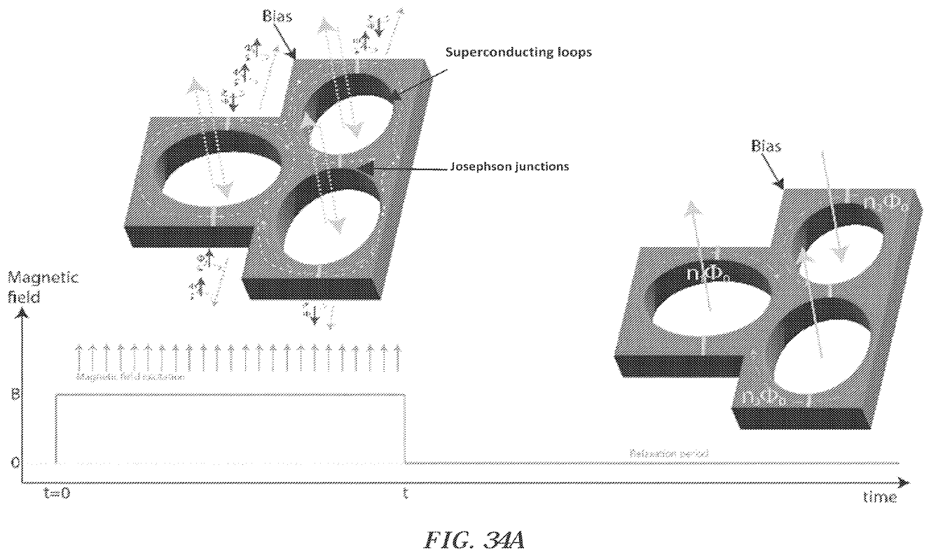

FIG. 33 shows disordered superconducting neural network (left) showing trapped flux configurations (memory states) and the corresponding circulating currents around loops. The neural network can be modeled using equivalent circuits with Josephson junctions and inductors. Disorder can be introduced through random choice of circuit parameters. The energy profile of a 2-dimensional disordered network is shown (right). Trapped flux in loops represent local energy minima. When excited, the energy profile dynamically changes before relaxing to a different configuration.

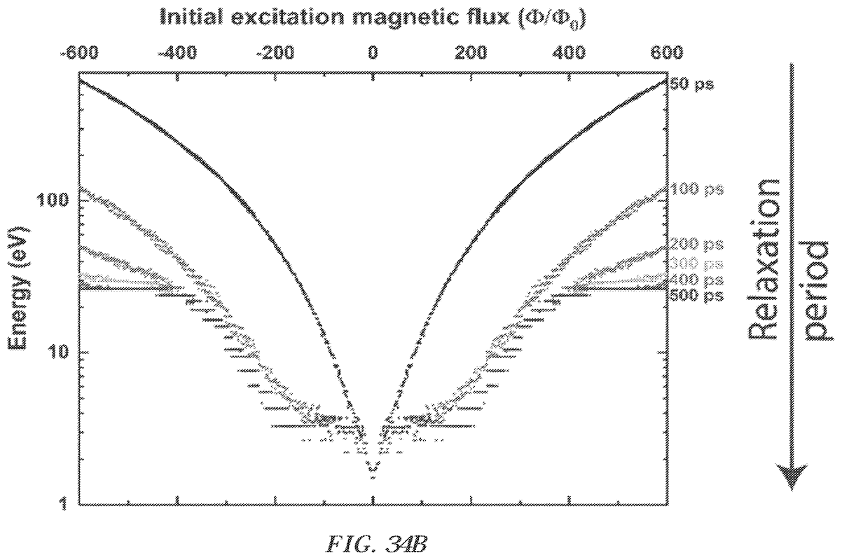

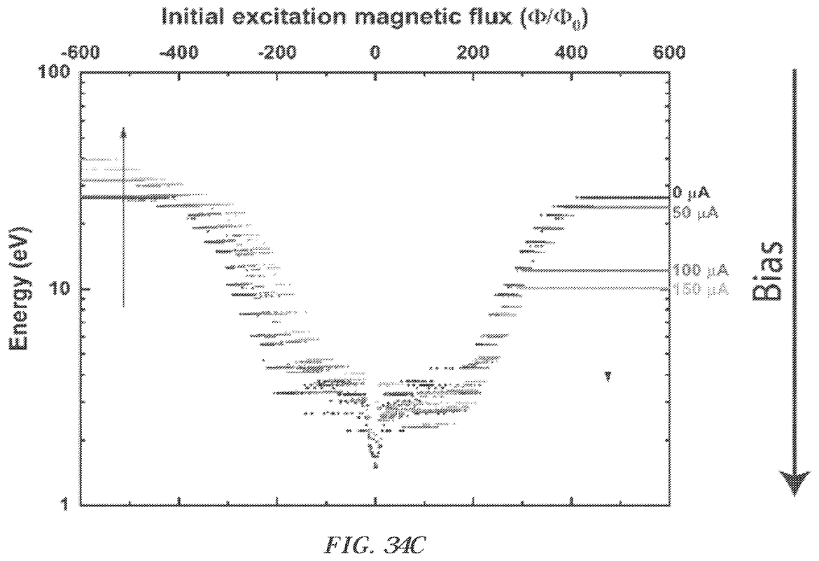

FIG. 34A shows 3-loop neural network under uniform magnetic field pulse excitation followed by a relaxation period. Different relaxed flux configurations/memory states can be accessed by exciting the network with different magnetic field pulse height and width. FIG. 34B shows trapped flux energy representing memory states as a function of different magnetic field pulse amplitudes. Different instances of time during the relaxation process shows that the states are dynamic, but discrete states can be realized after relaxation. FIG. 34C shows relaxed memory states with a constant bias current shows tilting of the energy profile. Excitation and bias together allow transitions between memory states.

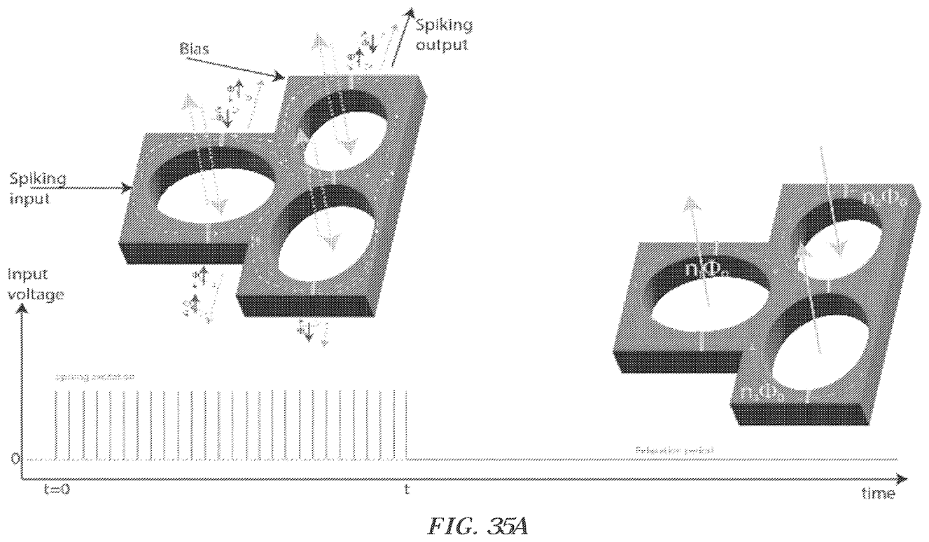

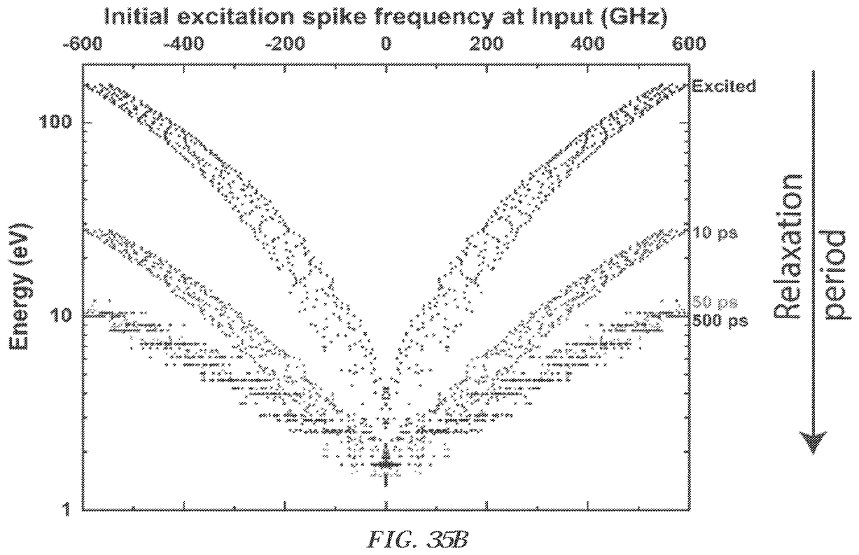

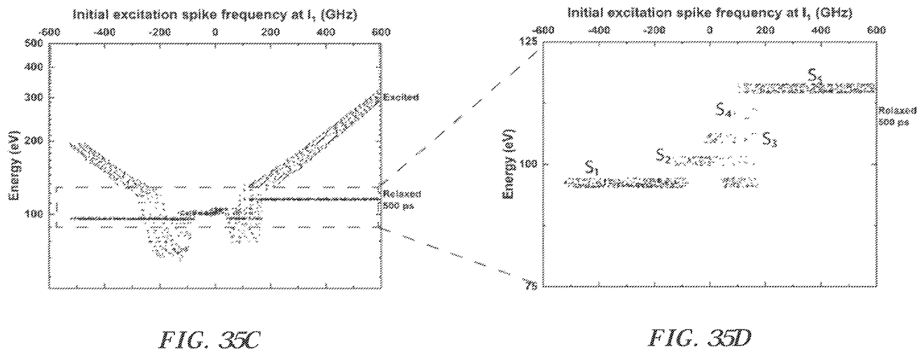

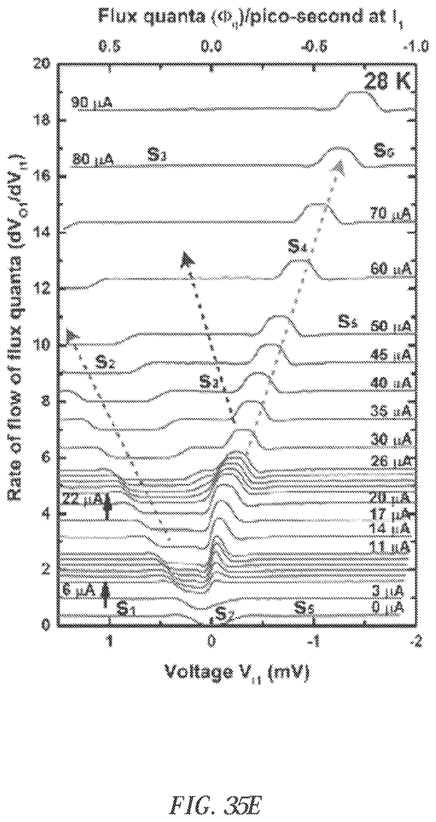

FIG. 35A shows 3-loop neural network with a spiking input excitation signal followed by a relaxation period. After relaxation, the trapped flux settles to a stable state. FIG. 35B shows trapped flux energy during and after relaxation following a spiking excitation. FIG. 35C shows when bias is turned ON during spiking excitation, the resulting memory states are classified into categories retained during and after excitation. FIG. 35D shows when relaxed, large energy barriers separate these classes of states (S₁-S₅). FIG. 35E shows experimental observation of classes of states (S₁-S₅) in the form of different rates of flow of flux at the output.

In some embodiments of the disclosed technology, a disordered neural network includes an array of dissimilar superconducting loops multiply coupled to each other inductively or through Josephson junctions linking them. Input and output channels carry spiking voltage signals (each spike representing a single flux-quantum). Information is encoded in the amplitude (i.e., the number of flux quanta) and the precise timing of the spikes. The feedback (or bias) signals are time-dependent continuous current signals that can be used to externally program the network behavior (supervised learning), or to connect to output channels through a feedback mechanism for unsupervised learning.

The disclosed technology can be implemented in some embodiments to provide a recurrent neural network architecture for neuromorphic processing. In some implementations, the first experimental demonstration of a simple 3-loop neural network to identify memory states. Recent additions to this include development of basic information storage, processing, and retrieval process for disordered neural networks. The networks store information in the form of trapped flux configurations as shown in FIG. 33. These flux configurations/memory states represent local energy minima and are stable. Different memory states can be accessed by exciting and then relaxing the network. The resulting memory state after relaxation depends on the applied excitation amplitude and duration. Example of a magnetic field excitation is shown in FIG. 34A. A uniform magnetic field pulse is applied to a 3-loop neural network that drives it into a dynamic state. The pulse amplitude is varied, with a constant pulse width, to access different memory states after a relaxation period of 500 ps. The results are shown in FIG. 34B. The energy profile can be distorted or modified by applying bias/feedback signals (FIG. 33). With a constant bias current, tilting of the energy states is achieved for uniform magnetic field excitation as shown in FIG. 34C. During neural network operation, spiking excitation is applied at one or more of the input channels. The number of spikes and the timing between them determines the final memory state. For each memory state, a new spike at the input has a different probability of a spiking event at the outputs, representing the synaptic weight between the input-output channel. For a spiking excitation of a constant frequency, the synaptic weight determines the rate of flow of flux between the channels.

The spiking input is a non-uniform excitation and therefore different input channels result in different energy profile. This represents a multi-dimensional memory state space corresponding to the energy profile shown in FIG. 33. A spiking input is applied to the 3-loop network and then allowed to relax as shown in FIG. 35A. Initially, no bias is applied. The results shown in FIG. 35B indicate that the network relaxes after 500 ps to reach a stable memory state. The memory states depend on the frequency of the applied input. This process describes the information writing/storage aspect of the neural network operation.

An important aspect of information processing in neural networks is classification/categorization. Classification of memory states found in disordered networks into categories can be achieved by applying time-varying input spiking signals and bias current signals together. The categories of memory states in a class are separated from other categories through significantly larger energy barriers. FIG. 35C shows the excited and relaxed memory states as a function of input spiking frequency with a constant current bias as shown in FIG. 35A. The resulting energy landscape is modified to represent different categories of states, that can be observed both when the excitation is active and after relaxation (FIG. 35C). When relaxed, the previous symmetrical distribution of memory states is modified and the memory states are redistributed into different categories separated by large energy barriers shown in FIG. 35D. The internal dynamics of the disordered array networks are numerically calculated using circuit simulations performed on the equivalent circuit model of the network as described earlier. These calculations allow us to identify the internal trapped flux configurations and their dynamics during excitation. Experimentally, the memory states can be addressed through the measurement of the rate of flow of flux between the input and the output channel. When both the spiking excitation and bias are applied, the state classes of states are retained. When an input excitation specific to one of the classes is applied, the output spiking signal represents a constant flow that can be used to identify the class of states. The states can be redistributed between classes by varying the bias. The experimental results corresponding to these observations are shown in FIG. 35E.

The circuit modeling and numerical calculations allow observation of internal dynamics of the networks and map them to the experimental results. Therefore, circuit modeling can be used to develop algorithms and network models for applications.

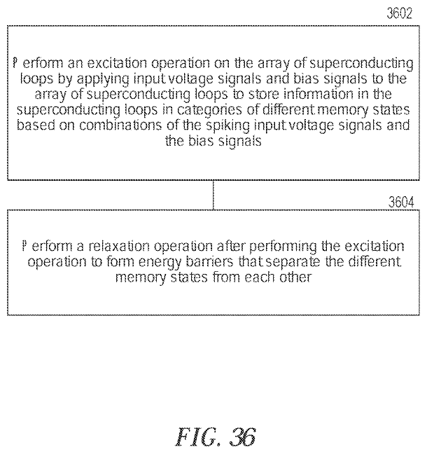

FIG. 36 shows an example method of storing information in an array of superconducting loops based on some implementations of the disclosed technology.

In some implementations, a method of storing information in an array of superconducting loops includes, at 3602, performing an excitation operation on the array of superconducting loops by applying input voltage signals and bias signals to the array of superconducting loops to store information in the superconducting loops in categories of different memory states based on combinations of the spiking input voltage signals and the bias signals, and at 3604, performing a relaxation operation after performing the excitation operation to form energy barriers that separate the different memory states from each other.

In some implementations, the input signals include spiking voltage pulses. In some implementations, the bias signals include continuous, time-varying currents.

In some implementations, the excitation operation further includes applying an excitation magnetic field pulse to the array of superconducting loops.

In some implementations, memory states corresponding to the information stored in the superconducting loops are determined based on an amplitude and duration of the excitation magnetic field pulse.

Therefore, various implementations of features of the disclosed technology can be made based on the above disclosure, including the examples listed below.

Example 1. A neural network comprising: a plurality of disordered superconducting loops, at least one of the superconducting loops coupled to one or more of the other superconducting loops through at least one of a Josephson junction or an inductor formed between the at least one of the superconducting loops and the one or more of the other superconducting loops; a plurality of input channels coupled to the neural network to apply input signals to the plurality of disordered superconducting loops; a plurality of output channels coupled to the neural network to receive output signals generated by the plurality of disordered superconducting loops in response to the input signals and transmit the output signals; and a plurality of bias signal channels coupled to the neural network to supply bias signals to the plurality of disordered superconducting loops.

Example 2. The neural network of example 1, wherein the superconducting loops are formed in a superconducting material.

Example 3. The neural network of example 1, wherein the Josephson junction is configured to generate single magnetic flux quantum voltage pulses when a current through the Josephson junction exceeds a threshold current value.

Example 4. The neural network of example 1, wherein the superconducting loops are configured to store magnetic flux quanta in a form of persistent loop currents to indicate a memory state corresponding to the magnetic flux quanta.

Example 5. The neural network of example 1, wherein the input and output signals include spiking voltage pulses.

Example 6. The neural network of example 1, wherein the bias signals include continuous, time-varying currents.

Example 7. The neural network of any of examples 1-6, further comprising a feedback loop coupling at least one of the output channels to at least one of the bias signal channels.

Example 8. The neural network of any of examples 1-6, further comprising a feed-forward loop coupling at least one of the output channels to a different neural network.

Example 9. A neural network comprising: an array of superconducting loops to store information, the superconducting loops multiply coupled to each other inductively or through Josephson junctions linking the superconducting loops; one or more input channels coupled to the array of superconducting loops to carry spiking input voltage signals to the array of superconducting loops; and one or more output channels coupled to the array of superconducting loops to carry spiking output voltage signals from the array of superconducting loops, wherein the information is encoded in an amplitude and a timing of the spiking input and output voltage signals.

Example 10. The neural network of example 9, wherein the superconducting loops have different shapes from each other.

Example 11. The neural network of example 9, wherein the amplitude of the spiking input and output voltage signals corresponds to a number of magnetic flux quanta.

Example 12. The neural network of example 9, further comprising one or more bias signal channels coupled to the array of superconducting loops to externally program a behavior of the neural network by applying time-dependent continuous current signals to the array of superconducting loops.

Example 13. The neural network of example 12, wherein the information stored in the superconducting loops is categorized into different memory states based on a combination of the spiking input voltage signals and the bias signals.

Example 14. The neural network of example 9, further comprising one or more feedback signal channels coupled to the array of superconducting loops to apply the spiking output voltage signals from the one or more output channels to the array of superconducting loops through the one or more feedback signal channels.

Example 15. The neural network of example 9, wherein the superconducting loops are configured to store the information corresponding to magnetic flux quanta that is trapped in the superconducting loops.

Example 16. The neural network of example 9, wherein the information is accessed by exciting and relaxing the array of superconducting loops.

Example 17. The neural network of example 9, wherein the superconducting loops are configured to store the information in response to application of an excitation magnetic field pulse to the array of superconducting loops and relaxation of the array of superconducting loops, wherein memory states corresponding to the information stored in the superconducting loops are determined based on an amplitude and duration of the excitation magnetic field pulse.

Example 18. The neural network of example 9, wherein in a case that the spiking input voltage signals have a constant frequency, a synaptic weight between the one or more input channels and the one or more output channels determines a flow rate of magnetic flux between the one or more input channels and the one or more output channels, wherein is the synaptic weight is obtained by dividing a number of the spiking output voltage signals by a number of the spiking input voltage signals.

Example 19. A method of storing information in an array of superconducting loops, comprising: performing an excitation operation on the array of superconducting loops by applying input voltage signals and bias signals to the array of superconducting loops to store information in the superconducting loops in categories of different memory states based on combinations of the spiking input voltage signals and the bias signals; and performing a relaxation operation after performing the excitation operation to form energy barriers that separate the different memory states from each other.

Example 20. The method of example 19, wherein the input signals include spiking voltage pulses.

Example 21. The method of example 19, wherein the bias signals include continuous, time-varying currents.

Example 22. The method of example 19, wherein the excitation operation further includes applying an excitation magnetic field pulse to the array of superconducting loops.

Example 23. The method of example 22, wherein memory states corresponding to the information stored in the superconducting loops are determined based on an amplitude and duration of the excitation magnetic field pulse.

Example 24. The method of example 19, wherein at least one of the superconducting loops is coupled to one or more of the other superconducting loops through at least one of a Josephson junction or an inductor formed between the at least one of the superconducting loops and the one or more of the other superconducting loops.

Example 25. A neural network device comprising: a disordered array of superconducting loops disposed in a superconducting material, wherein at least one of the superconducting loops is coupled to at least one of adjacent superconducting loops to form a first junction via a first link; a plurality of input nodes coupled to a first end of the superconducting material and configured to receive input signals; a plurality of output nodes coupled to a second end of the superconducting material and configured to provide output signals; and a plurality of biasing signal nodes structured to apply biasing signals across the superconducting material.

Example 26. The device of example 25, wherein the first junction includes a Josephson junction.

Example 27. The device of example 26, wherein the Josephson junction is configured to generate a signal propagation in a form of single-flux quantum voltage pulses when a current through the Josephson junction exceeds a threshold current value.

Example 28. The device of example 25, wherein the input and output signals include spiking voltage pulses.

Example 29. The device of example 25, wherein the biasing signals include continuous, time-varying currents.

Example 30. The device of example 25, further comprising a feedback loop couples at least one of the output nodes to at least one of the biasing signal nodes.

Example 31. The device of example 25, further comprising a feedback loop couples at least one of the input nodes to at least one of the output nodes.

Implementations of the subject matter and the functional operations described in this patent document can be implemented in various systems, digital electronic circuitry, or in computer software, firmware, or hardware, including the structures disclosed in this specification and their structural equivalents, or in combinations of one or more of them. Implementations of the subject matter described in this specification can be implemented as one or more computer program products, i.e., one or more modules of computer program instructions encoded on a tangible and non-transitory computer readable medium for execution by, or to control the operation of, data processing apparatus. The computer readable medium can be a machine-readable storage device, a machine-readable storage substrate, a memory device, a composition of matter effecting a machine-readable propagated signal, or a combination of one or more of them. The term “data processing unit” or “data processing apparatus” encompasses all apparatus, devices, and machines for processing data, including by way of example a programmable processor, a computer, or multiple processors or computers. The apparatus can include, in addition to hardware, code that creates an execution environment for the computer program in question, e.g., code that constitutes processor firmware, a protocol stack, a database management system, an operating system, or a combination of one or more of them.

A computer program (also known as a program, software, software application, script, or code) can be written in any form of programming language, including compiled or interpreted languages, and it can be deployed in any form, including as a stand-alone program or as a module, component, subroutine, or other unit suitable for use in a computing environment. A computer program does not necessarily correspond to a file in a file system. A program can be stored in a portion of a file that holds other programs or data (e.g., one or more scripts stored in a markup language document), in a single file dedicated to the program in question, or in multiple coordinated files (e.g., files that store one or more modules, sub programs, or portions of code). A computer program can be deployed to be executed on one computer or on multiple computers that are located at one site or distributed across multiple sites and interconnected by a communication network.

The processes and logic flows described in this specification can be performed by one or more programmable processors executing one or more computer programs to perform functions by operating on input data and generating output. The processes and logic flows can also be performed by, and apparatus can also be implemented as, special purpose logic circuitry, e.g., an FPGA (field programmable gate array) or an ASIC (application specific integrated circuit).

Processors suitable for the execution of a computer program include, by way of example, both general and special purpose microprocessors, and any one or more processors of any kind of digital computer. Generally, a processor will receive instructions and data from a read only memory or a random access memory or both. The essential elements of a computer are a processor for performing instructions and one or more memory devices for storing instructions and data. Generally, a computer will also include, or be operatively coupled to receive data from or transfer data to, or both, one or more mass storage devices for storing data, e.g., magnetic, magneto optical disks, or optical disks. However, a computer need not have such devices. Computer readable media suitable for storing computer program instructions and data include all forms of nonvolatile memory, media and memory devices, including by way of example semiconductor memory devices, e.g., EPROM, EEPROM, and flash memory devices. The processor and the memory can be supplemented by, or incorporated in, special purpose logic circuitry.

While this patent document contains many specifics, these should not be construed as limitations on the scope of any invention or of what may be claimed, but rather as descriptions of features that may be specific to particular embodiments of particular inventions. Certain features that are described in this patent document in the context of separate embodiments can also be implemented in combination in a single embodiment. Conversely, various features that are described in the context of a single embodiment can also be implemented in multiple embodiments separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. Moreover, the separation of various system components in the embodiments described in this patent document should not be understood as requiring such separation in all embodiments.

Only a few implementations and examples are described and other implementations, enhancements and variations can be made based on what is described and illustrated in this patent document.

1. A neural network, comprising:
a plurality of disordered superconducting loops, at least one of the superconducting loops coupled to one or more of the other superconducting loops through at least one of a Josephson junction or an inductor formed between the at least one of the superconducting loops and the one or more of the other superconducting loops;
a plurality of input channels coupled to the neural network to apply input signals to the plurality of disordered superconducting loops;
a plurality of output channels coupled to the neural network to receive output signals generated by the plurality of disordered superconducting loops in response to the input signals and transmit the output signals; and
a plurality of bias signal channels coupled to the neural network to supply bias signals to the plurality of disordered superconducting loops.

2. The neural network of claim 1, wherein the superconducting loops are formed in a superconducting material.

3. The neural network of claim 1, wherein the Josephson junction is configured to generate single magnetic flux quantum voltage pulses when a current through the Josephson junction exceeds a threshold current value.

4. The neural network of claim 1, wherein the superconducting loops are configured to store magnetic flux quanta in a form of persistent loop currents to indicate a memory state corresponding to the magnetic flux quanta.

5. The neural network of claim 1, wherein the input and output signals include spiking voltage pulses.

6. The neural network of claim 1, wherein the bias signals include continuous, time-varying currents.

7. The neural network of claim 1, further comprising a feedback loop coupling at least one of the output channels to at least one of the bias signal channels.

8. The neural network of claim 1, further comprising a feed-forward loop coupling at least one of the output channels to a different neural network.

9. A neural network, comprising:
an array of superconducting loops to store information, the superconducting loops multiply coupled to each other inductively or through Josephson junctions linking the superconducting loops;
one or more input channels coupled to the array of superconducting loops to carry spiking input voltage signals to the array of superconducting loops; and
one or more output channels coupled to the array of superconducting loops to carry spiking output voltage signals from the array of superconducting loops,
wherein the information is encoded in an amplitude and a timing of the spiking input and output voltage signals.

10. The neural network of claim 9, wherein the superconducting loops have different shapes from each other.

11. The neural network of claim 9, wherein the amplitude of the spiking input and output voltage signals corresponds to a number of magnetic flux quanta.

12. The neural network of claim 9, further comprising one or more bias signal channels coupled to the array of superconducting loops to externally program a behavior of the neural network by applying time-dependent continuous current signals to the array of superconducting loops.

13. The neural network of claim 12, wherein the superconducting loops are configured to store the information in categories of different memory states based on a combination of the spiking input voltage signals and the bias signals.

14. The neural network of claim 9, further comprising one or more feedback signal channels coupled to the array of superconducting loops to apply the spiking output voltage signals from the one or more output channels to the array of superconducting loops through the one or more feedback signal channels.

15. The neural network of claim 9, wherein the superconducting loops are configured to store the information corresponding to magnetic flux quanta that is trapped in the superconducting loops.

16. The neural network of claim 9, wherein the information is accessed by exciting and relaxing the array of superconducting loops.

17. The neural network of claim 9, wherein the superconducting loops are configured to store the information in response to application of an excitation magnetic field pulse to the array of superconducting loops and relaxation of the array of superconducting loops, wherein memory states corresponding to the information stored in the superconducting loops are determined based on an amplitude and duration of the excitation magnetic field pulse.

18. The neural network of claim 9, wherein in a case that the spiking input voltage signals have a constant frequency, a synaptic weight between the one or more input channels and the one or more output channels determines a flow rate of magnetic flux between the one or more input channels and the one or more output channels, wherein is the synaptic weight is obtained by dividing a number of the spiking output voltage signals by a number of the spiking input voltage signals.

19. A method of storing information in an array of superconducting loops, comprising:
performing an excitation operation on the array of superconducting loops by applying input voltage signals and bias signals to the array of superconducting loops to store information in the superconducting loops in categories of different memory states based on combinations of the input voltage signals and the bias signals; and
performing a relaxation operation after performing the excitation operation to form energy barriers that separate the different memory states from each other.

20. The method of claim 19, wherein the input voltage signals include spiking voltage pulses.

21. The method of claim 19, wherein the bias signals include continuous, time-varying currents.

22. The method of claim 19, wherein the excitation operation further includes applying an excitation magnetic field pulse to the array of superconducting loops.

23. The method of claim 22, wherein memory states corresponding to the information stored in the superconducting loops are determined based on an amplitude and duration of the excitation magnetic field pulse.

24. The method of claim 19, wherein at least one of the superconducting loops is coupled to one or more of the other superconducting loops through at least one of a Josephson junction or an inductor formed between the at least one of the superconducting loops and the one or more of the other superconducting loops.
